(19) United States
(12) Patent Application Publication
(10) Pub. No.: US 2026/0198121 A1
(43) Pub. Date: Jul. 9, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Kai-Yun YANG, Tainan City (TW); Stan LEE, Tainan City (TW); Chun-Hao CHOU, Tainan City (TW)

(21) Appl. No.: 19/014,708

(22) Filed: Jan. 9, 2025

(51) Int. Cl. H10F 39/00

(52) U.S. Cl. CPC H10F 39/807; H10F 39/018; H10F 39/809

(57) ABSTRACT

A liner for an isolation structure is formed in a device layer of a semiconductor device using one or more high dielectric constant (high-k) dielectric materials. The high-k dielectric material(s) of the liner have a dielectric constant that is greater than the dielectric constant of silicon nitride (SiₓN_{y}), which enables increased passivation to be achieved for the isolation, and enables reduced current leakage to be achieved for integrated circuit structures in the device layer. The isolation structure and/or the liner may be formed by processes that are compatible with subsequent layers and/or structures that are to be formed in the semiconductor device.

### BACKGROUND

Various semiconductor device packing techniques may be used to incorporate one or more semiconductor dies into a semiconductor package. In some cases, semiconductor dies may be horizontally interconnected through an interposer. Additionally and/or alternatively, semiconductor dies may be arranged vertically in a semiconductor package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of example implementations of a deep trench isolation (DTI) structure described herein.

FIGS. 3A-3E are diagrams of an example implementation of forming a semiconductor device described herein.

FIGS. 4A-4I are diagrams of an example implementation of forming a semiconductor device described herein.

FIGS. 5A-5I are diagrams of an example implementation of forming a semiconductor device described herein.

FIG. 6 is a diagram of an example semiconductor device described herein.

FIGS. 7A-7D are diagrams of example implementations of a DTI structure described herein.

FIGS. 8A-8E are diagrams of an example implementation of forming the semiconductor device described herein.

FIGS. 9A-9E are diagrams of an example implementation of forming a semiconductor device described herein.

FIGS. 10A-10E are diagrams of an example implementation of forming a semiconductor device described herein.

FIGS. 11A-11O are diagrams of an example implementation of forming a semiconductor device described herein.

FIGS. 12A-12C are diagrams of an example implementation of forming a semiconductor device described herein.

FIG. 13 is a diagram of an example semiconductor device described herein.

FIGS. 14A and 14B are diagrams of example implementations of a DTI structure described herein.

FIG. 15 is a diagram of an example semiconductor device described herein.

FIGS. 16A-16D are diagrams of example implementations of a DTI structure described herein.

FIGS. 17A and 17B are diagrams of an example semiconductor device described herein.

FIG. 18 is a diagram of example implementation of a DTI structure described herein.

FIGS. 19A-19K are diagrams of an example implementation of forming a semiconductor device described herein.

FIG. 20 is a flowchart of an example process associated with forming a semiconductor device described herein.

FIG. 21 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die in a semiconductor package may include various types of isolation structures in a device layer of the semiconductor die. The isolation structures may be included to provide electrical isolation for integrated circuit structures in the device layer, and/or to electrically isolate various regions of the semiconductor die. Examples of such isolation structures include shallow trench isolation (STI) structures and deep trench isolation (DTI) structures, among other examples. STI structures may provide electrical isolation near the surface of the device layer, whereas DTI structures extend further into the device layer than the STI structures and provide electrical isolation deeper into the device layer.

In some cases, one or more liners may be included between an isolation structure and the device layer of the semiconductor die. The liner(s) may provide passivation for the isolation structure, and may enhance the electrical isolation provided by the isolation structure by increasing nominal voltage, reducing current leakage, and/or reducing power consumption of the integrated circuit structures isolated by the isolation structure.

However, the liners for the isolation structure may be formed by complex processes, some of which may be incompatible with structures that have already been formed in the semiconductor die. Moreover, the liners may be formed of materials that may contaminate layers and structures that are formed after the isolation structure, resulting in reduces performance for these layers and structures, and/or increasing the likelihood of defects and failures in the semiconductor die.

In some implementations described herein, a liner for an isolation structure is formed in a device layer of a semiconductor device (e.g., a semiconductor die, a semiconductor structure) using one or more high dielectric constant (high-k) dielectric materials. The high-k dielectric material(s) of the liner have a dielectric constant that is greater than the dielectric constant of silicon nitride (SiₓN_{y}), which enables increased passivation to be achieved for the isolation, and enables reduced current leakage to be achieved for integrated circuit structures in the device layer.

The isolation structure and/or the liner may be formed by processes that are compatible with subsequent layers and/or structures that are to be formed in the semiconductor device. For example, the isolation structure may be a DTI structure, and an STI structure may be formed on the DTI structure such that the STI structure is located between the liner and the front side surface of the device layer. In this way, the STI structure acts as a buffer and protects subsequent layers and/or structures formed above the front side surface of the device layer from being contaminated by the high-k dielectric material(s) of the liner.

Additionally and/or alternatively, the DTI structure and the associated liner may be formed on the back side of the device layer. A dummy DTI structure and a dummy liner may be formed in the front side of the device layer and subsequently replaced from the back side of the device layer with the DTI structure and the associated liner. This enables the recess for the DTI structure to be formed using plasma-based processes prior to formation of layers and/or structures being formed above the front side of the device layer, while the back side processing protects subsequent layers and/or structures formed above the front side surface of the device layer from being contaminated by the high-k dielectric material(s) of the liner.

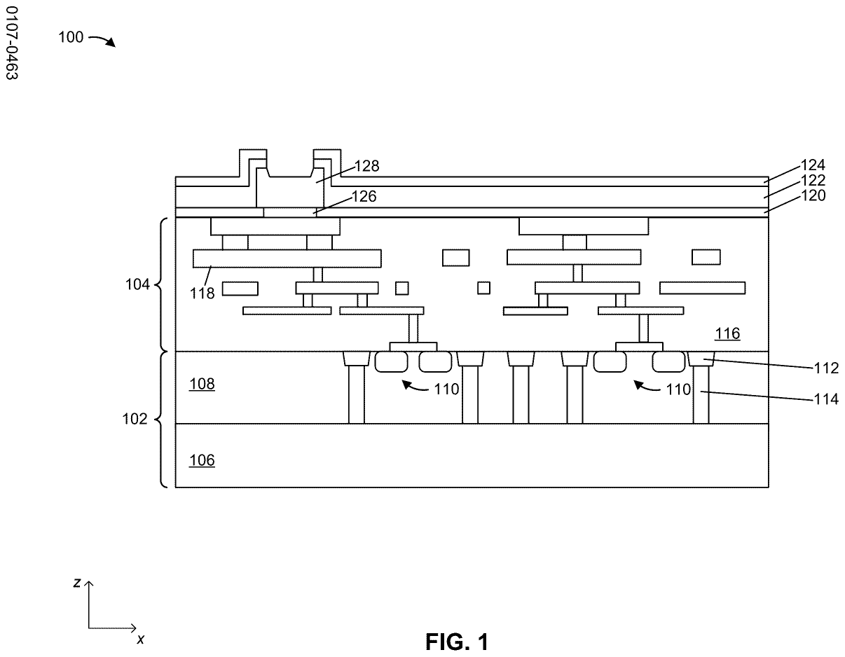

FIG. 1 is a diagram of an example semiconductor device 100 described herein. FIG. 1 illustrates a cross-section view of the semiconductor device 100. The semiconductor device 100 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 100 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die.

As further shown in FIG. 1, the semiconductor device 100 may include a device layer 102 and an interconnect layer 104 above the device layer 102 such that the device layer 102 and the interconnect layer 104 are stacked and vertically arranged (e.g., in a z-direction) in the semiconductor device 100.

The device layer 102 may correspond to a portion of a semiconductor wafer on which the semiconductor device 100 formed. The device layer 102 may include one or more semiconductor layers, such as a semiconductor layer 106 and/or a semiconductor layer 108, among other examples. The semiconductor layer(s) 106, 108 may each include a layer of silicon (Si), a layer of semiconductor material including silicon, a layer of III-V compound semiconductor material such as gallium arsenide (GaAs), and/or another type of semiconductor material. In some implementations, the semiconductor layer 106 corresponds to a semiconductor wafer, and the semiconductor layer 108 corresponds to a layer of epitaxially-grown semiconductor material that is grown on the semiconductor wafer.

The device layer 102 may include integrated circuit structures 110 of the semiconductor device 100. The integrated circuit structures 110 may each include transistors (e.g., planar transistors, fin field effect transistors (finFETs), gate all around (GAA) transistors), photodiodes, pixel sensors, capacitors, resistors, inductors, photodetectors, transceivers, transmitters, receives, optical circuits, and/or other types of passive and/or active integrated circuit devices.

As further shown in FIG. 1, various types of isolation structures may be included in the device layer 102 to provide electrical isolation for the integrated circuit structures 110. For example, one or more STI structures 112 may be included in the device layer 102 (e.g., in the semiconductor layer 108 of the device layer 102). As another example, one or more DTI structures 114 may be included in the device layer 102 (e.g., in the semiconductor layer 108 of the device layer 102).

The STI structures 112 may provide shallow isolation in the device layer 102 and may extend into the semiconductor layer 108 from a front side of the device layer 102. The front side of the device layer 102 corresponds to a side of the device layer 102 facing the interconnect layer 104, whereas the back side of the device layer 102 corresponds to a side of the device layer 102 vertically opposing the front side in the z-direction.

The DTI structures 114 may provide electrical isolation further into the device layer 102 and may extend from the STI structures 112 to the semiconductor layer 106 in the z-direction. In some implementations, DTI structures 114 are included to provide optical isolation, such as in implementations in which one or more associated integrated circuit structures 110 are photodiodes, photodetectors, and/or another type of structure that is configured to sense incident light. A DTI structure 114 may have a greater vertical (z-direction) height or thickness than an STI structure 112. A DTI structure 114 may be located under an STI structure 112 such that the STI structure 112 and the DTI structure 114 are stacked and vertically arranged in the z-direction.

The STI structures 112 and the DTI structures 114 may each include one or more types of dielectric materials such as a silicon oxide (SiOₓ), a silicon nitride (SiₓN_{y}), silicon carbide (SiC), silicon oxynitride (SiON), and/or another suitable dielectric material. Additionally and/or alternatively, an STI structure 112 and/or a DTI structure 114 may include polysilicon, one or more metals, and/or one or more other materials.

The interconnect layer 104 of the semiconductor device 100 includes one or more dielectric layers 116 that are arranged in a direction (e.g., z-direction) that is approximately perpendicular to the device layer 102. The dielectric layer(s) 116 may include backend dielectric layers (e.g., interlayer dielectric (ILD) layers, intermetal dielectric (IMD) layers) and etch stop layers (ESLs) that are arranged in an alternating manner in the interconnect layer 104. The dielectric layer(s) 116 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 104 may include a plurality of layers of conductive structures 118 (e.g., electrically conductive structures) in the dielectric layer(s) 116. The conductive structures 118 are electrically coupled and/or physically coupled with one or more of the integrated circuit structures 110 in the device layer 102, and are electrically interconnected together in the interconnect layer 104. The conductive structures 118 correspond to circuit routing that enables signals and/or power to be provided to and/or from the integrated circuit structures 110. The conductive structures 118 may include a combination of conductive structures that extend primarily horizontally in the interconnect layer 104 (e.g., trenches, conductive lines) and that are interconnected by interconnects (e.g., vias) that extend primarily vertically in the interconnect layer 104. The conductive structures 118 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive structures 118 may be arranged in alternating layers of metallization layers (referred to as “M”-layers) and via layers (referred to as “V”-layers). Each metallization layer may include one or more conductive structures laterally arranged in the interconnect layer 104, and each via layer may include one or more interconnects that interconnect the metallization layers in the interconnect layer 104. As an example, a metal-0 (M0) layer may be located at the bottom of the interconnect layer 104 and may be coupled with the integrated circuit structures 110 in the device layer 102, a via-0 (V0) layer may be located above and coupled with the M0 layer in the interconnect layer 104, a metal-1 (M1) layer may be located above and coupled with the V0 layer in the interconnect layer 104, a via-1 (V1) layer may be located above and coupled with the M1 layer in the interconnect layer 104, a metal-2 (M2) layer may be located above and electrically coupled with the V1 layer in the interconnect layer 104, and so on. In some implementations, the interconnect layer 104 includes nine (9) stacked metallization layers (e.g., M0-M8). In other implementations, the contact layer (referred to as “CO”-layer) may be located at the bottom of the interconnect layer 104 and may be coupled with the integrated circuit structures 110 in the device layer 102, a metal-1 (M1) layer may be located above and coupled with the CO layer in the interconnect layer 104, and so on. In some implementations, the interconnect layer 104 includes another quantity of stacked metallization layers.

As further shown in FIG. 1, one or more passivation layer(s) 120-124 may be included on the interconnect layer 104. The passivation layer(s) 120-124 may be included to provide electrical passivation for the conductive structures 118 in the interconnect layer 104 as well as connection pads 126 and connection structures 128 above the interconnect layer 104. The passivation layer(s) 120-124 may one or a combination of high-k passivation layers and/or low-k passivation layers. The connection pads 126 and the connection structures 128 may enable the semiconductor device 100 to be electrically connected to a socket, to another semiconductor device, to wire bonds, and/or to another type of external electrical connection. The connection pads 126 and the connection structures 128 may include one or more conductive materials, such as copper (Cu), gold (Au), silver (Ag), nickel (Ni), tin (Sn), ruthenium (Ru), cobalt (Co), tungsten (W), titanium (Ti), aluminum (Al), one or more metals, and/or a combination thereof, one or more conductive ceramics, and/or another type of conductive material.

As indicated above, FIG. 1 is provided as an example. Other examples may differ from what is described with regard to FIG. 1.

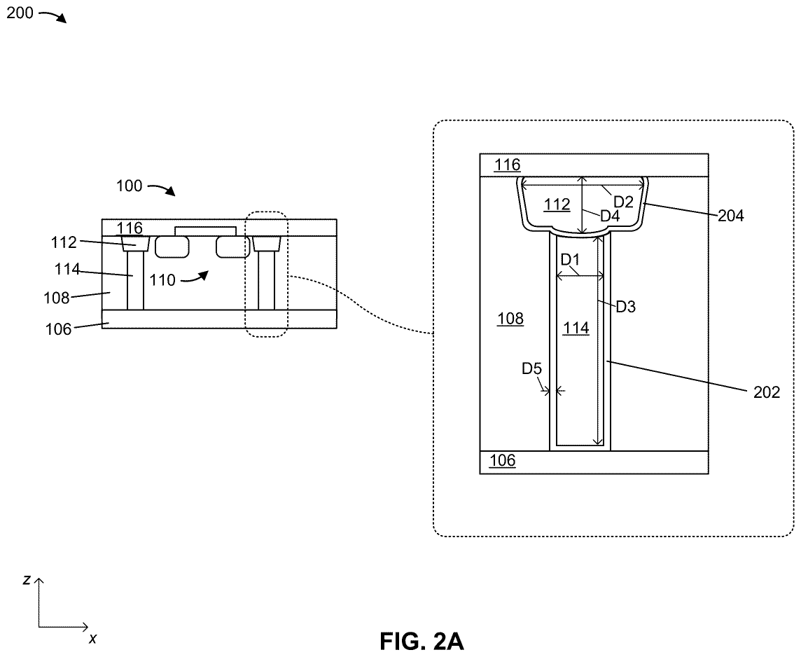

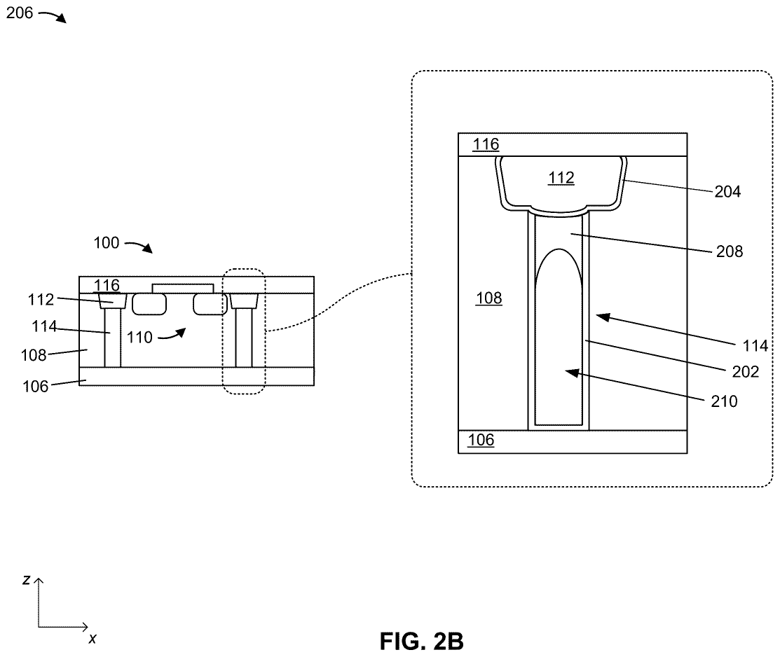

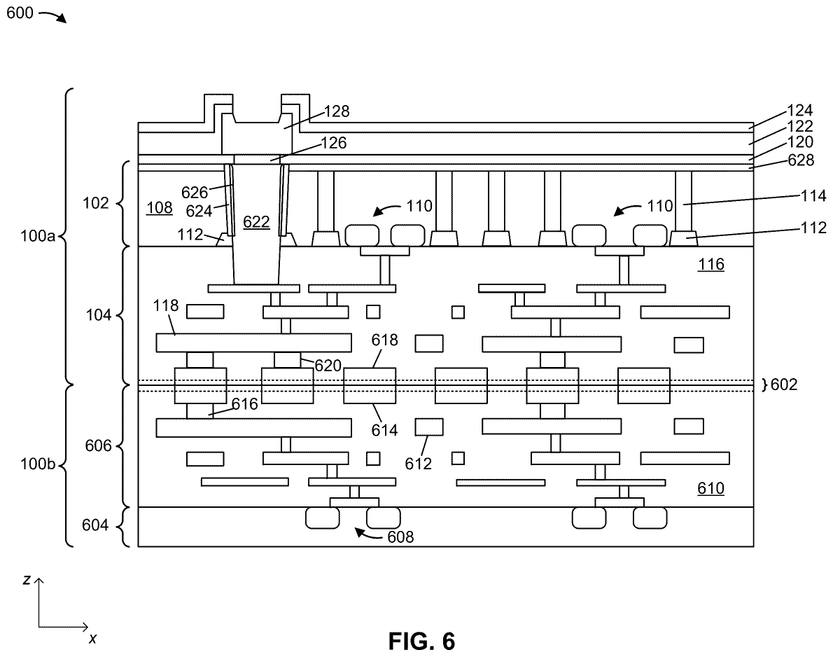

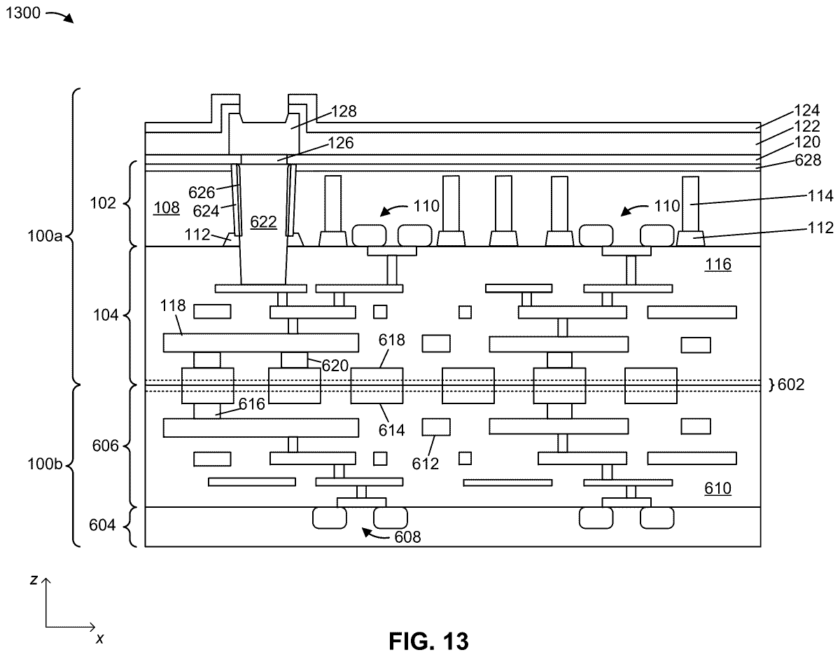

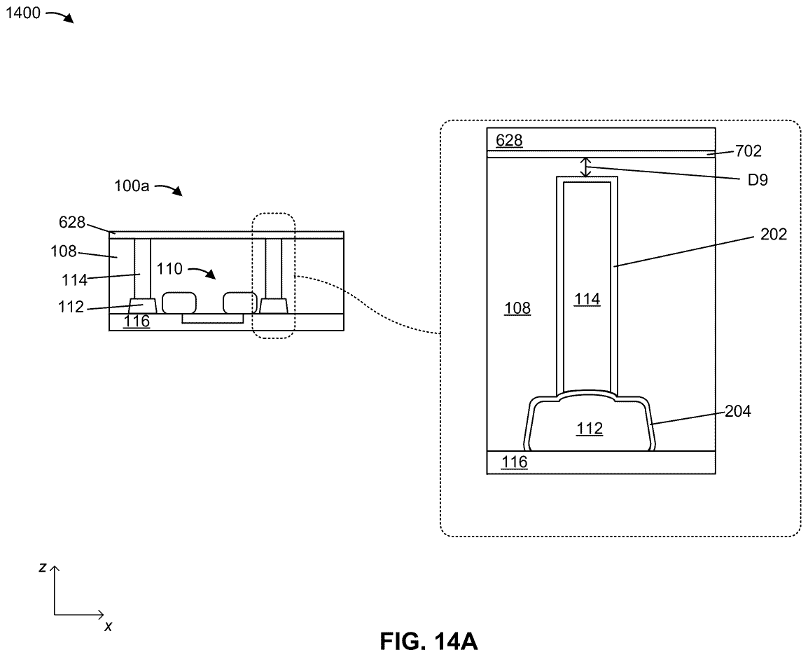

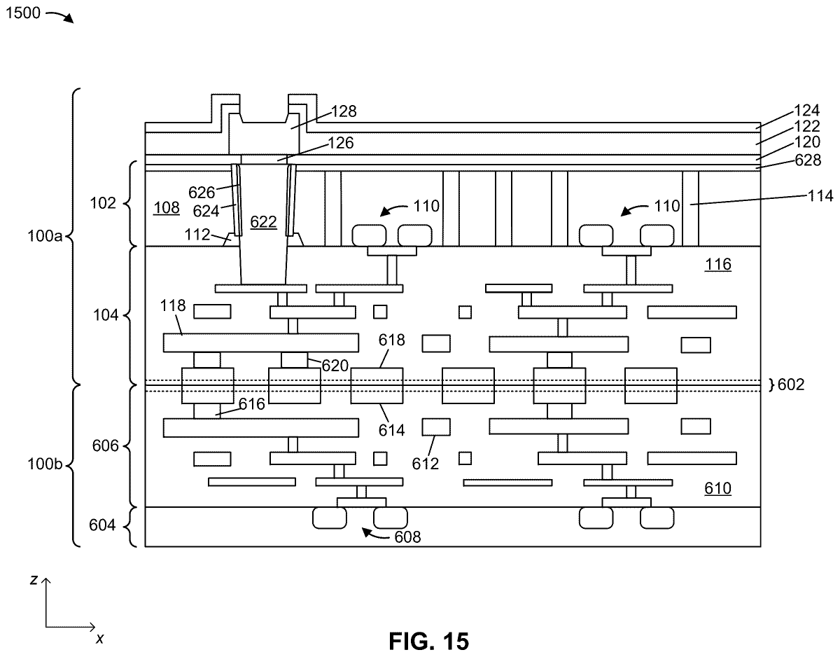

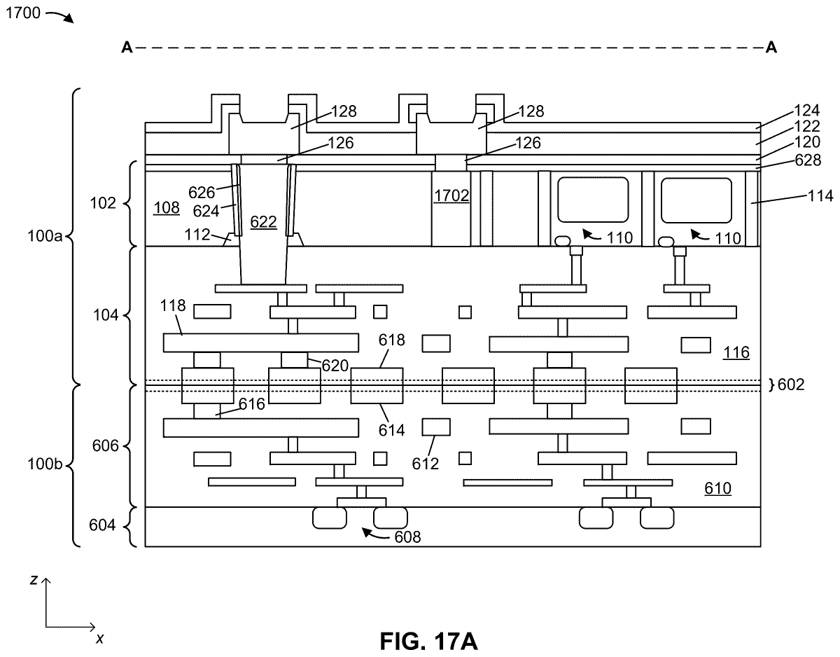

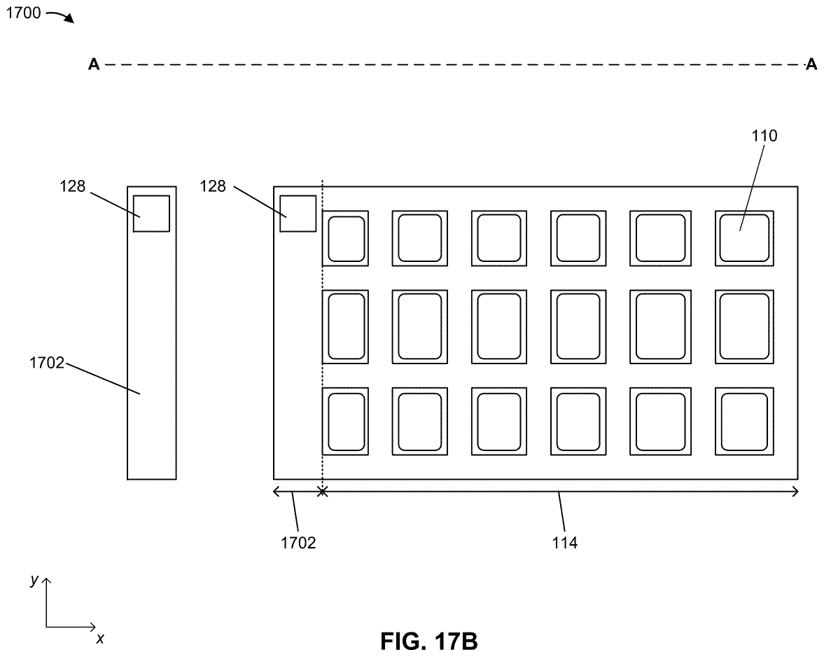

FIGS. 2A and 2B are diagrams of example implementations of a DTI structure 114 described herein. The example implementations of DTI structures 114 illustrated in FIGS. 2A and 2B may be implemented in one or more semiconductor devices described herein, such as the semiconductor device 100, a semiconductor device 600 illustrated and described in connection with FIG. 6, a semiconductor device 1300 illustrated and described in connection with FIG. 13, a semiconductor device 1500 illustrated and described in connection with FIG. 15, a semiconductor device 1700 illustrated and described in connection with FIGS. 17A and 17B, and/or another semiconductor device.

FIG. 2A illustrates an example implementation 200 of a DTI structure 114. As shown in FIG. 2A, the DTI structure 114 may extend through the semiconductor layer 108 of the device layer 102. The DTI structure 114 may be located vertically between the semiconductor layer 106 (e.g., the substrate of the semiconductor device 100) and an STI structure 112 in the semiconductor layer 108. Thus, in the example implementation 200, the top surface of the DTI structure 114 is below the front side surface of the device layer 102.

The DTI structure 114 may be elongated in the z-direction such that a lateral width of the DTI structure 114 (dimension D1) is less than a lateral width of the STI structure 112 (dimension D2). In some implementations, a ratio of the dimension D2 to the dimension D1 (D2:D1) is included in a range of approximately 2:1 to approximately 10:1. However, other values and ranges are within the scope of the present disclosure. Moreover, a vertical height of the DTI structure 114 (dimension D3) is greater than a vertical height of the STI structure 112 (dimension D4). In some implementations, a ratio of the dimension D3 to the dimension D4 (D3:D4) is included in a range of approximately 10:1 to approximately 50:1. However, other values and ranges are within the scope of the present disclosure.

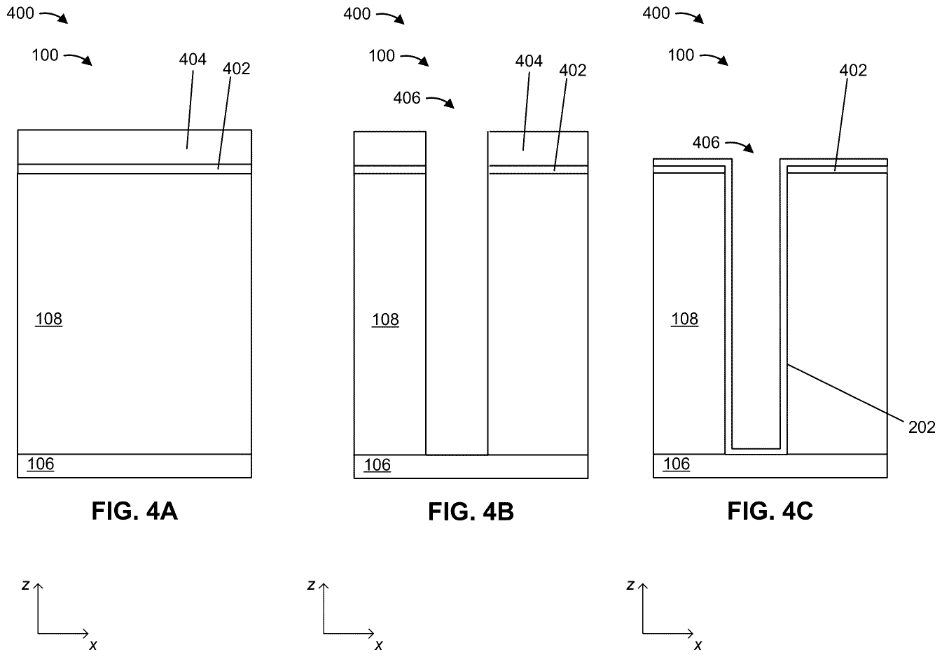

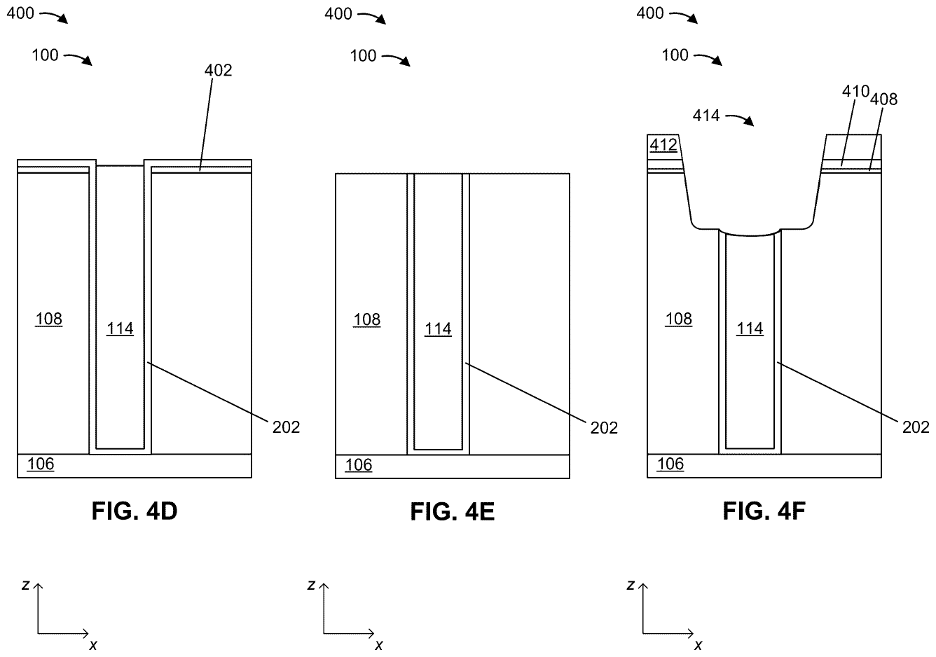

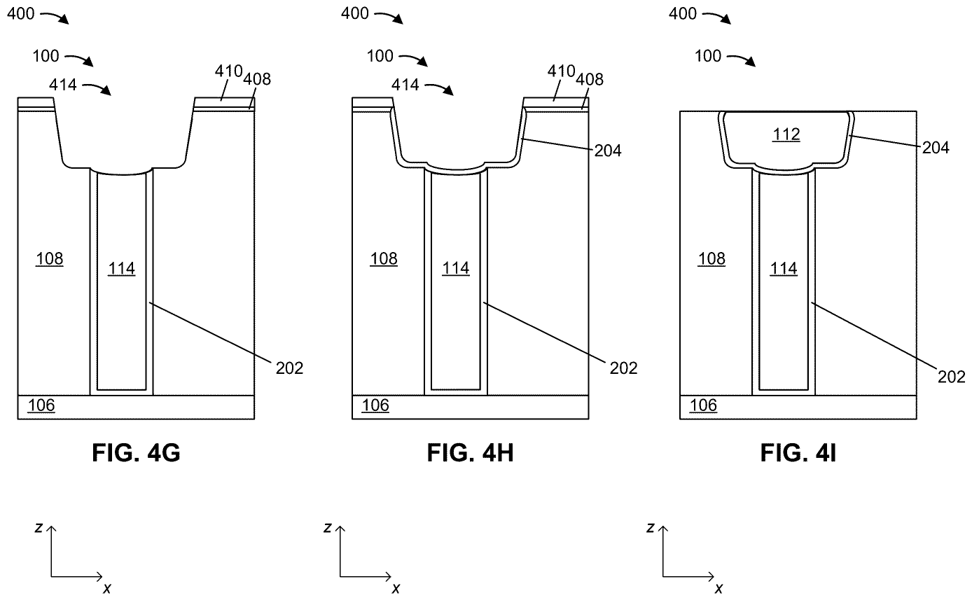

As further shown in FIG. 2A, one or more liners are included between the DTI structure 114 and the semiconductor layer 108 of the device layer 102. In particular, a high-k dielectric liner 202 is included between the semiconductor layer 108 of the device layer 102 and the sidewalls of the DTI structure 114. As described in greater detail in connection with FIGS. 4A-4I, the DTI structure 114 and the high-k dielectric liner 202 in the example implementation 200 are formed from the front side of the device layer 102. Accordingly, the high-k dielectric liner 202 may also be located between the bottom surface of the DTI structure 114 and the semiconductor layer 106 of the device layer 102. In some implementations, a low-k dielectric liner, such as a silicon oxide (SiOₓ) liner, may be included between the high-k dielectric liner 202 and the semiconductor layer 108.

One or more liners 204 may be included between the STI structure 112 and the semiconductor layer 108 of the device layer 102. As described in greater detail in connection with FIGS. 4A-4I, the STI structure 112 may be formed after (e.g., formed on) the DTI structure 114. Accordingly, the liner(s) 204 may be located on the top of the DTI structure 114 between the DTI structure 114 and the STI structure 112.

The liner(s) 204 may include one or more low-k dielectric materials such as a silicon oxide (SiOₓ), an undoped silicate glass (USG), a boron-containing silicate glass (BSG), and/or a fluorine-containing silicate glass (FSG), among other examples. In some implementations, the liner(s) 204 include a nitride-containing dielectric liner such as a silicon nitride material (e.g., SiₓN_{y} such as Si₃N₄), a silicon oxynitride (SiON), and/or another suitable nitride-containing dielectric material.

The high-k dielectric material of the high-k dielectric liner 202 has a dielectric constant that is higher than the dielectric constant of the liner(s) 204. The higher dielectric constant of the high-k dielectric liner 202 enables the high-k dielectric liner 202 to provide increased electrical isolation (e.g., compared to including a low-k dielectric liner or a silicon nitride liner around the DTI structure 114). Thus, including the high-k dielectric liner 202 around the DTI structure 114 enables a low amount of current leakage from the integrated circuit structures 110 to be achieved.

In some implementations, the high-k dielectric liner 202 includes a high-k oxide dielectric material having a dielectric constant that is greater than the dielectric constant of silicon nitride (Si₃N₄). For example, the high-k dielectric liner 202 may include a high-k oxide dielectric material having a dielectric constant that is at least approximately 7 to 10 or greater. Examples of such high-k oxide dielectric materials include an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the high-k dielectric liner 202 includes a multiple-layer thin film, where each layer includes a different high-k dielectric material.

In some implementations, the high-k dielectric liner 202 may have a thickness (dimension D5) that is included in a range of approximately 0.5 nanometers to approximately 3 nanometers. However, other values and ranges are within the scope of the present disclosure.

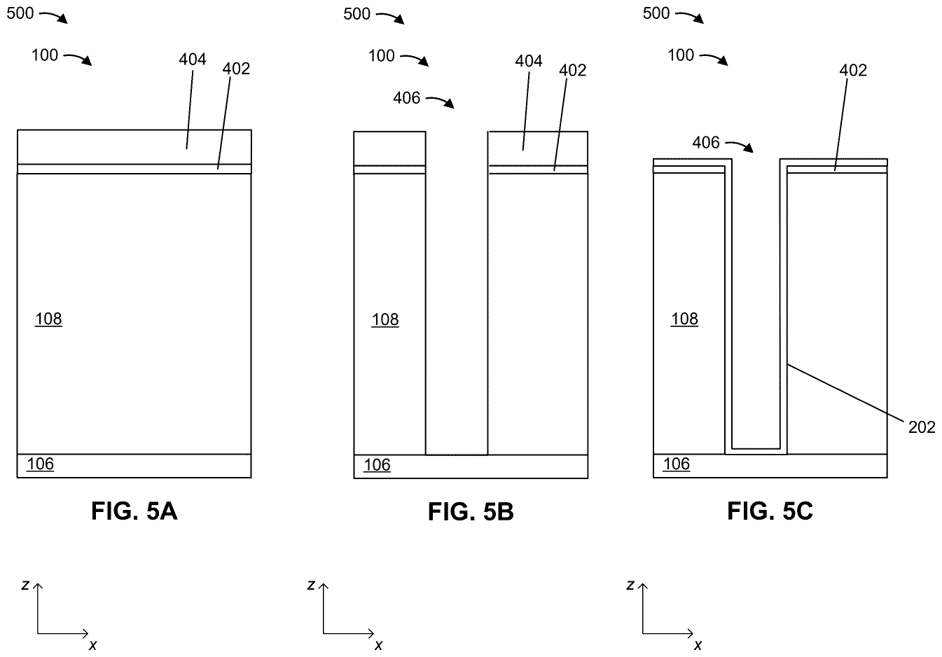

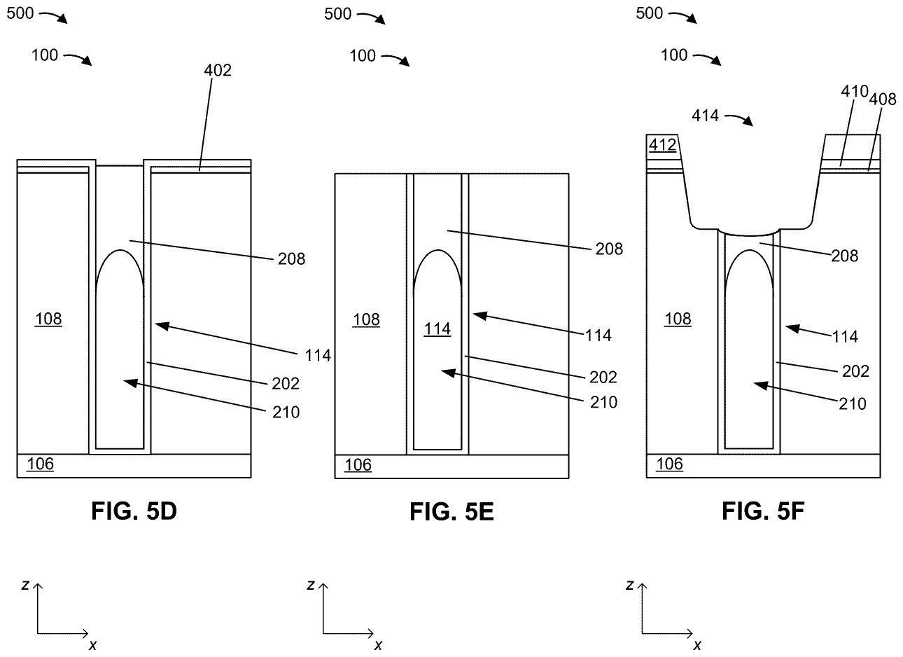

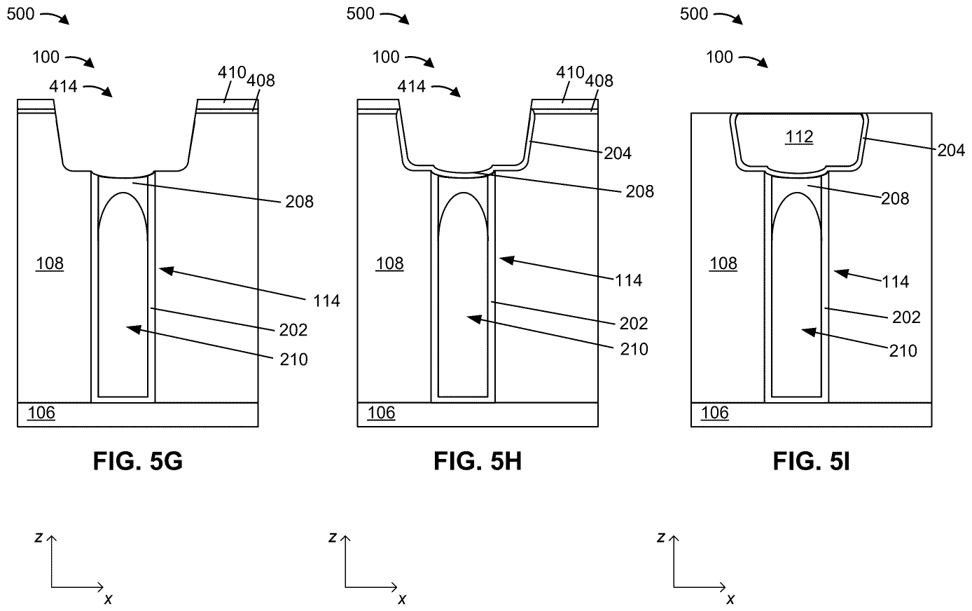

FIG. 2B illustrates an example implementation 206 of a DTI structure 114. As shown in FIG. 2B, the example implementation 206 of the DTI structure 114 is similar to the example implementation 200. However, in the example implementation 206, the DTI structure 114 includes a plug 208 at the top of the DTI structure 114. As described in greater detail in connection with FIGS. 5A-5I, the plug 208 is formed in a manner such that the plug 208 seals a recess in which the DTI structure 114 is formed before the recess is fully filled in with material of the plug 208, resulting in the remaining area of the recess corresponding to an air gap 210. Thus, in the example implementation 206, the DTI structure 114 includes an air gap 210 at the bottom of the DTI structure 114, and a plug 208 at the top of the DTI structure 114.

The air gap 210 is filled in with a gas. For example, the air gap 210 may contain nitrogen (N₂), argon (Ar), oxygen (O₂), and/or another gas. The dielectric constant of the air gap 210 is lower than the dielectric constant of other dielectric materials such as silicon oxide (SiO₂), and therefore may enable a lower parasitic capacitance to be achieved for the DTI structure 114.

As shown in FIG. 2B, the sidewalls of the plug 208 may be in contact with the high-k dielectric liner 202. Moreover, the sides and the bottom of the air gap 210 may also be in contact with the high-k dielectric liner 202. The plug 208 may be located vertically (e.g., in the z-direction) between the air gap 210 and the STI structure 112 above the DTI structure 114.

The plug 208 may include one or more types of dielectric materials such as a silicon oxide (SiOₓ), a silicon nitride (SiₓN_{y}), silicon carbide (SiC), silicon oxynitride (SiON), and/or another suitable dielectric material. Additionally and/or alternatively, the plug 208 may include polysilicon, one or more metals, and/or one or more other materials.

In some implementations, the bottom surface of the plug 208 has a concave cross-sectional profile, as shown in the example in FIG. 2B. In some implementations, the bottom surface of the plug 208 has another concave cross-sectional profile, such as a convex cross-sectional profile or a flat cross-sectional profile.

As indicated above, FIGS. 2A and 2B are provided as examples. Other examples may differ from what is described with regard to FIGS. 2A and 2B.

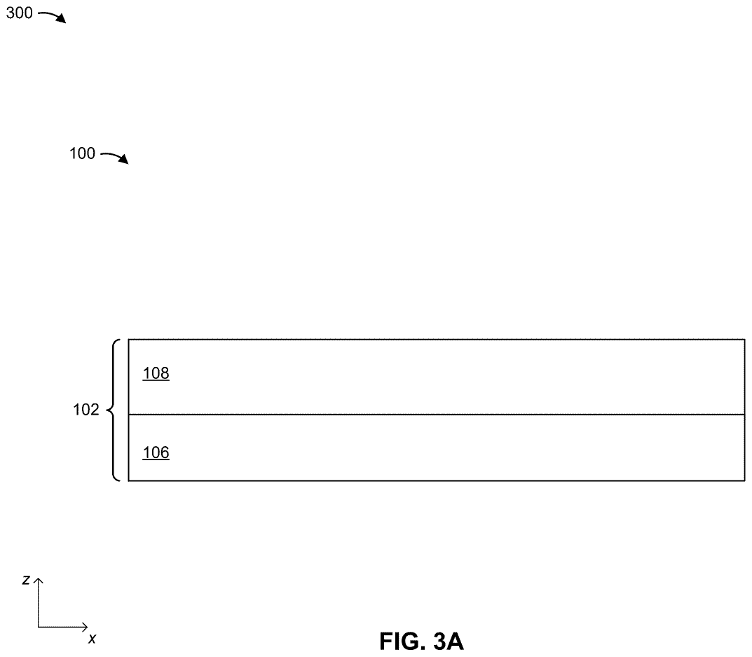

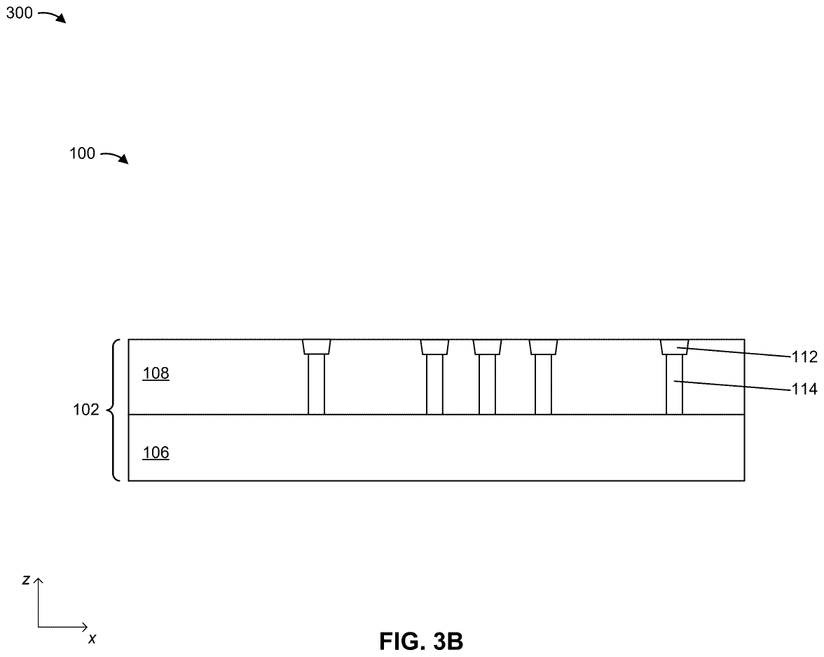

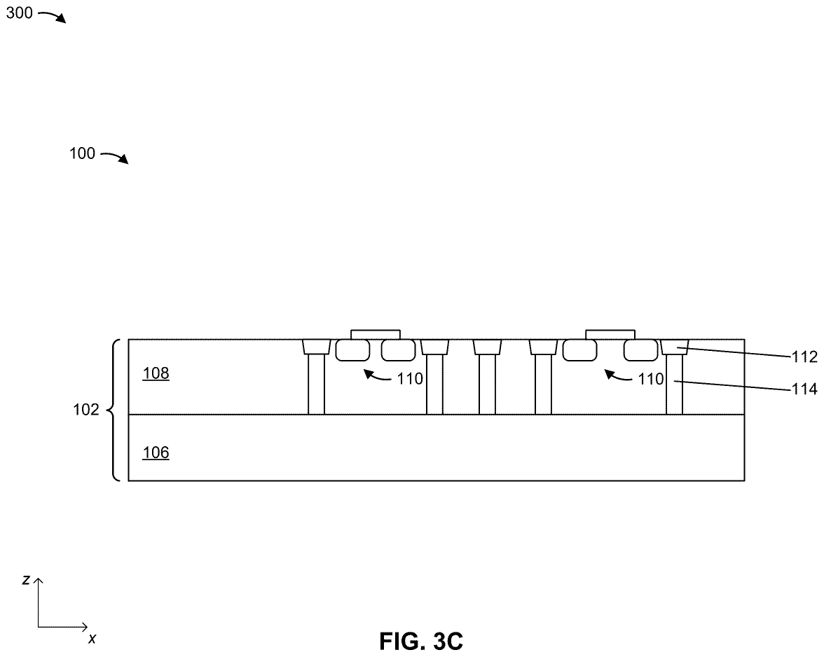

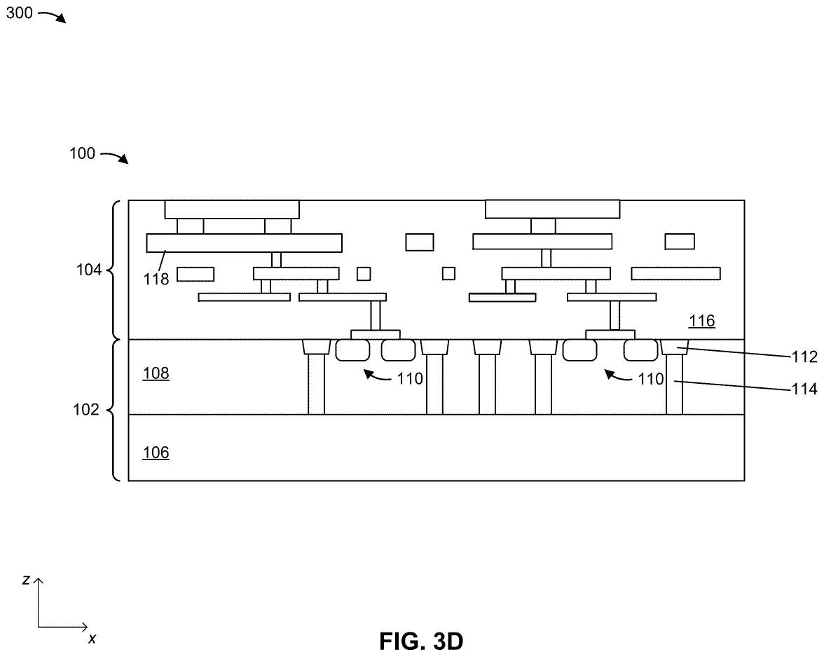

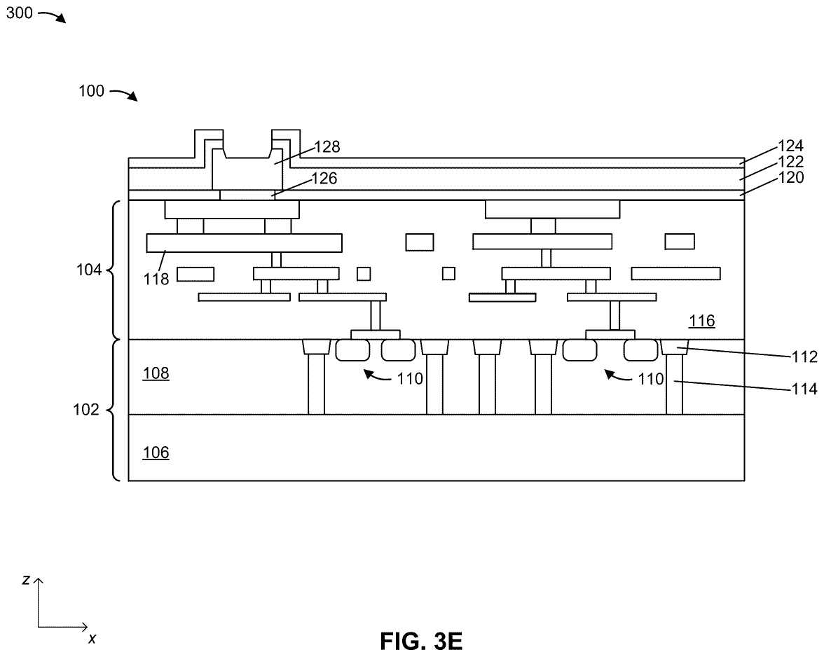

FIGS. 3A-3E are diagrams of an example implementation 300 of forming a semiconductor device described herein. In some implementations, the example implementation 300 includes an example process for forming the semiconductor device 100 or a portion thereof. In some implementations, one or more of the operations described in connection with the example implementation 300 may be performed to form another semiconductor device described herein, such as a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 300, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 3A, one or more of the operations in the example implementation 300 may be performed in connection with the semiconductor layer of the device layer 102 of the semiconductor device 100. In some implementations, the semiconductor layer 106 of the device layer 102 may be provided in the form of a semiconductor wafer or another type of semiconductor substrate. In some implementations, a deposition tool is used to form or deposit the semiconductor layer 108 on the semiconductor layer 106 by epitaxial growth.

As shown in FIG. 3B, isolation structures may be formed in the semiconductor layer 108 of the device layer 102. For example, the DTI structures 114 may be formed in the semiconductor layer 108 from the front side of the device layer 102, and the STI structures 112 may be formed on the DTI structures 114 from the front side of the device layer 102. In some implementations, additional STI structures 112 may be formed in the front side of the device layer 102 such that the additional STI structures 112 are not located over DTI structures 114. Examples of forming STI structures 112 and DTI structures 114 are illustrated and described in connection with FIGS. 4A-4I and 5A-5I.

As shown in FIG. 3C, the integrated circuit structures 110 may be formed in and/or on the device layer 102 of the semiconductor device 100. One or more semiconductor processing tools may be used to form one or more portions of the integrated circuit structures 110. For example, a deposition tool may be used to perform various deposition operations to deposit layers of the integrated circuit structures 110, and/or to deposit photoresist layers for etching the semiconductor layer 108 of the device layer 102 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer 108 and/or portions of the deposited layers to form the integrated circuit structures 110. As another example, a planarization tool may be used to planarize portions of the integrated circuit structures 110. As another example, an ion implantation tool may be used to implant ions in the semiconductor layer 108 to dope portions of the semiconductor layer 108 of the device layer 102 with one or more types of dopants (e.g., p-type dopants, n-type dopants).

As shown in FIG. 3D, the interconnect layer 104 of the semiconductor device 100 may be formed over and/or on the device layer 102. One or more semiconductor processing tools may be used to form the interconnect layer 104 by forming one or more dielectric layers 116 and forming a plurality of conductive structures 118 in the dielectric layer(s) 116. For example, a deposition tool may be used to deposit a first layer of the dielectric layer(s) 116 (e.g., using a chemical vapor deposition (CVD) technique, an atomic layer deposition (ALD) technique, a physical vapor deposition (PVD) technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 118 in the recesses (e.g., using a CVD technique, an ALD technique, a PVD technique, an electroplating technique, and/or another type of deposition technique). At least a portion of the first layer of conductive structures 118 may be electrically connected and/or physically connected with the integrated circuit structures 110 in the device layer 102 (e.g., directly connected or connected through contacts). Similar processing operations may be performed to form additional layers of the interconnect layer 104 until a sufficient or desired arrangement of conductive structures 118 is achieved.

As shown in FIG. 3E, the passivation layer(s) 120-124, the connection pads 126, and the connection structures 128 may be formed above the interconnect layer 104. In some implementations, a deposition tool may be used to deposit the passivation layer 120 using a CVD technique, an ALD technique, a PVD technique, and/or another type of deposition technique. A planarization tool may be used to perform a planarization operation (e.g., a chemical mechanical planarization (CMP) operation) to planarize the passivation layer 120. A deposition tool may be used to deposit a patterning layer (e.g., a photoresist layer by spin-coating deposition), an exposure tool and a developer tool may be used to form a pattern in the patterning layer, and an etch tool may be used to etch the passivation layer 120 based on the pattern to form a recess in the passivation layer 120. A deposition tool may be used to deposit a connection pad 126 in the recess such that the connection pad 126 lands on (and is electrically coupled to) a conductive structure 118 in the interconnect layer 104.

Alternatively, a layer of electrically conductive material may be deposited over the interconnect layer 104, and the layer of electrically conductive material may be patterned and etched to define the connection pad 126. The passivation layer 120 may then be formed around the connection pad 126. The connection structure 128 may be formed in a similar manner, and the passivation layers 122 and 124 may be formed around and over the connection structure 128. The passivation layers 122 and 124 on the connection structure 128 may be etched to expose the connection structure 128 so that an external connection can be formed to the connection structure 128.

As indicated above, FIGS. 3A-3E are provided as an example. Other examples may differ from what is described with regard to FIGS. 3A-3E.

FIGS. 4A-4I are diagrams of an example implementation 400 of forming a semiconductor device described herein. In some implementations, the example implementation 400 includes an example process for forming the example implementation 200 of the STI structure 112 and the DTI structure 114 illustrated in FIG. 2A. In some implementations, one or more of the operations described in connection with the example implementation 400 may be performed to form an STI structure 112 and a DTI structure 114 in a semiconductor device described herein, such as the semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 400, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 4A, a patterning stack may be formed above the semiconductor layer 108 of the device layer 102. A deposition tool may be used to deposit a hard mask layer 402 of the patterning stack using a PVD technique, an ALD technique, a CVD technique, an oxidation technique, and/or another suitable deposition technique. A deposition tool may be used to deposit a photoresist layer 404 of the pattering stack on the hard mask layer 402 using a spin-coating technique and/or another suitable deposition technique.

As shown in FIG. 4B, a pattern may be formed in the photoresist layer 404 and transferred to the hard mask layer 402. The pattern may be used to etch the semiconductor layer 108 to form a recess 406. An exposure tool may be used to expose the photoresist layer 404 to a radiation source to pattern the photoresist layer 404. A developer tool may be used to develop and remove portions of the photoresist layer 404 to expose the pattern. An etch tool may be used to etch the hard mask layer 402 based on the pattern to transfer the pattern to the hard mask layer 402, and an etch tool may be used to etch the semiconductor layer 108 from the front side of the device layer 102 based on the pattern to form the recess 406. Thus, the recess 406 is formed into the front side of the device layer 102 prior to formation of the interconnect layer 104. In some implementations, the etch operation includes a dry etch operation (e.g., a plasma-based etch operation, a gas-based etch operation), a wet chemical etch operation, and/or another type of etch operation.

As shown in FIG. 4C, a photoresist removal tool may be used to remove the remaining portions of the photoresist layer 404 (e.g., using a chemical stripper, plasma ashing, and/or another technique). As further shown in FIG. 4C, the high-k dielectric liner 202 is formed in the recess 406 from the front side of the device layer 102 prior to formation of the interconnect layer 104. A deposition tool may be used to deposit the high-k dielectric liner 202 using a conformal deposition technique such as ALD and/or CVD so that the high-k dielectric liner 202 conforms to the sidewalls and bottom surface of the recess 406. In some implementations, the bottom surface of the recess 406 corresponds to the top surface of the semiconductor layer 106. Accordingly the high-k dielectric liner 202 at the bottom of the recess 406 may be formed on the semiconductor layer 106. In some implementations, a low-k dielectric liner (now shown) is first formed on the sidewalls and bottom surface of the recess 406, and the high-k dielectric liner 202 is formed on the low-k dielectric liner.

As shown in FIG. 4D, the remaining area in the recess 406 may be filled in (e.g., from the front side of the device layer 102 prior to formation of the interconnect layer 104) with material of a DTI structure 114. In some implementations, a deposition tool is used to deposit dielectric material in the recess 406 (e.g., using a CVD technique, a PVD technique, an ALD technique, and/or another suitable deposition technique) to form the DTI structure 114 in the recess 406. In some implementations, a deposition tool is used to deposit polysilicon material in the recess 406 (e.g., using a CVD technique, a PVD technique, an ALD technique, and/or another suitable deposition technique) to form the DTI structure 114 in the recess 406. In some implementations, a deposition tool is used to deposit metal material in the recess 406 (e.g., using a CVD technique, a PVD technique, an ALD technique, an electroplating technique, and/or another suitable deposition technique) to form the DTI structure 114 in the recess 406.

As shown in FIG. 4E, a planarization tool may be used to perform a planarization operation such as a CMP operation to remove material of the high-k dielectric liner 202, material of the DTI structure 114, and/or material of the hard mask layer 402 from the top surface of the semiconductor layer 108. The planarization operation may result in the top of the DTI structure 114 being approximately co-planar with the top of the semiconductor layer 108. In some implementations, some amount of dishing may occur in the top of the DTI structure 114. As a result, the top of the DTI structure 114 may be slightly recessed or concave.

As shown in FIG. 4F, another pattering stack may be formed over the semiconductor layer 108 and over the DTI structure 114. The other patterning stack may include one or more hard mask layers 408, 410 and a photoresist layer 412. A pattern may be formed in the photoresist layer 412 and transferred to the hard mask layers 408, 410 in a similar manner as described above in connection with FIG. 4B, and the pattern may be used to etch the semiconductor layer 108 to form another recess 414 in the semiconductor layer 108. An etch tool may be used to etch the semiconductor layer 108 based on the pattern to form the recess 414 in the front side of the semiconductor layer 108 (e.g., prior to formation of the interconnect layer 104). In some implementations, a top portion of the DTI structure 114 and the associated portions of the high-k dielectric liner 202 along the sides of the top portion of the DTI structure 114 may be removed to form the recess 414. Thus, the recess 414 is formed and located above the DTI structure 114.

As shown in FIG. 4G, a photoresist removal tool may be used to remove the remaining portions of the photoresist layer 412 (e.g., using a chemical stripper, plasma ashing, and/or another technique).

As shown in FIG. 4H, the liner(s) 204 may be formed in the recess 414 from the front side of the device layer 102 prior to formation of the interconnect layer 104. A deposition tool may be used to deposit the liner(s) 204 using a conformal deposition technique such as ALD and/or CVD so that the liner(s) 204 conform to the sidewalls and bottom surface of the recess 414. In some implementations, the bottom surface of the recess 414 corresponds to the top surface of the DTI structure 114. Accordingly the liner(s) 204 at the bottom of the recess 414 may be formed on the top of the DTI structure 114. Portions of the liner(s) 204 may also be in contact with portions of the high-k dielectric liner 202 at the top of the DTI structure 114.

As shown in FIG. 4I, the remaining area in the recess 414 may be filled in (e.g., from the front side of the device layer 102 prior to formation of the interconnect layer 104) with material of an STI structure 112. In some implementations, a deposition tool is used to deposit dielectric material in the recess 414 (e.g., using a CVD technique, a PVD technique, an ALD technique, and/or another suitable deposition technique) to form the STI structure 112 in the recess 414. In some implementations, a deposition tool is used to deposit polysilicon material in the recess 414 (e.g., using a CVD technique, a PVD technique, an ALD technique, and/or another suitable deposition technique) to form the STI structure 112 in the recess 414.

As further shown in FIG. 4I, a planarization tool may be used to perform a planarization operation such as a CMP operation to remove material of the liner(s) 204, material of the STI structure 112, and/or material of the hard mask layers 408, 410 from the top surface of the semiconductor layer 108. The planarization operation may result in the top of the STI structure 112 being approximately co-planar with the top of the semiconductor layer 108. In some implementations, some amount of dishing may occur in the top of the STI structure 112. In some implementations, the top of the STI structure 112 may be higher than the top of the semiconductor layer 108. As a result, the top of the STI structure 112 may be slightly recessed or concave.

In this way, the DTI structure 114 and the associated high-k dielectric liner 202 are formed during front side processing of the semiconductor device 100. Similarly, the STI structure 112 and the liner(s) 204 are also formed during front side processing of the semiconductor device 100. Thus, the DTI structure 114 and the associated high-k dielectric liner 202, and the STI structure 112 and the associated liner(s) 204, are formed prior to formation of the interconnect layer 104. The types of high-k material(s) of the high-k dielectric liner 202 may be selected to prevent, minimize, and/or otherwise reduce the likelihood of contamination of layers and/or structures formed after the DTI structure 114, and/or to prevent, minimize, and/or otherwise reduce the likelihood of damage to the high-k dielectric liner 202 that might otherwise occur due to high temperature processes performed after formation of the high-k dielectric liner 202.

As indicated above, FIGS. 4A-4I are provided as an example. Other examples may differ from what is described with regard to FIGS. 4A-4I.

FIGS. 5A-5I are diagrams of an example implementation 500 of forming a semiconductor device described herein. In some implementations, the example implementation 500 includes an example process for forming the example implementation 206 of the STI structure 112 and the DTI structure 114 illustrated in FIG. 2B. In some implementations, one or more of the operations described in connection with the example implementation 500 may be performed to form an STI structure 112 and a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 500, such as a deposition tool, an exposure tool, a developer tool, an etch tool, a planarization tool, a plating tool, an ion implantation tool, an annealing tool, a bonding tool, and/or another type of semiconductor processing tool.

As shown in FIGS. 5A-5I, the example implementation 500 includes a similar combination of operations as illustrated and described in connection with FIGS. 4A-4I for the example implementation 400. However, instead of fully filling in the recess 406 with the material of the DTI structure 114 (e.g., as in the example implementation 400), material of a plug 208 is deposited at a high deposition rate to cause the material of the plug 208 to seal the top of the recess 406 before the recess 406 is fully filled in with material. This results in the unfilled volume within the recess 406 corresponding to an air gap 210 of the DTI structure 114.

A deposition tool may be used to deposit the material of the plug 208 using a deposition technique that has low step coverage performance. In other words, the deposition technique that is used to deposit the material of the plug 208 may result in deposited material accumulating at a faster rate at the top of the recess 406 and on the semiconductor layer 108 than at the bottom of the recess 406. Examples of such deposition techniques may include atmospheric pressure CVD, low-pressure CVD (LPCVD), and/or sputtering (e.g., PVD), among other examples.

As shown in FIG. 5F, the recess 414 that is formed for the STI structure 112 may be formed to a depth that is above the air gap 210. In other words, the recess 414 that is formed for the STI structure 112 may be formed so as to not punch through the plug 208 and so as to not open up the air gap 210. If the air gap 210 is opened during formation of the recess 414, material of the STI structure 112 might otherwise be deposited into the air gap 210, thereby increasing the parasitic capacitance of the DTI structure 114.

As indicated above, FIGS. 5A-5I are provided as an example. Other examples may differ from what is described with regard to FIGS. 5A-5I.

FIG. 6 is a diagram of an example semiconductor device 600 described herein. FIG. 6 illustrates a cross-section view of the semiconductor device 600. The semiconductor device 600 may be a semiconductor package that includes a plurality of semiconductor structures 100a, 100b (e.g., semiconductor dies) that bonded at a bonding interface 602 such that the semiconductor structures 100a, 100b are stacked and vertically arranged (e.g., in the z-direction) in the semiconductor device 600. The bond between the semiconductor structures 100a, 100b may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor structures 100a, 100b by forming metal-to-metal bonds and/or dielectric-to-dielectric bonds at the bonding interface 602 between the semiconductor structures 100a, 100b.

The semiconductor structure 100a may be similar to the semiconductor device 100 illustrated and described in connection with FIG. 1, and may include a similar combination and arrangement of layers and/or structures 102-128. The semiconductor structure 100b may also be similar to the semiconductor device 100, and may include a device layer 604 (similar to the device layer 102), an interconnect layer 606 (similar to the interconnect layer 104), integrated circuit structures 608 (similar to the integrated circuit structures 110), one or more dielectric layers 610 (similar to the dielectric layer(s) 116), and conductive structures 612 (similar to the conductive structures 118). In some implementations, the integrated circuit structures 608 and the integrated circuit structures 110 are different types of integrated circuit structures and/or implement different types of functions.

The interconnect layer 606 of the semiconductor structure 100b may include a plurality of bonding pads 614. The bonding pads 614 may be electrically coupled with the conductive structures 612 in the interconnect layer 606 by bonding vias 616. Similarly, the interconnect layer 104 of the semiconductor structure 100a may include a plurality of bonding pads 618. The bonding pads 618 may be electrically coupled with the conductive structures 118 in the interconnect layer 104 by bonding vias 620. The bonding pads 614, 618 and the bonding vias 616, 620 may each include tungsten (W), cobalt (Co), ruthenium (Ru), titanium (Ti), aluminum (Al), copper (Cu), gold (Au), and/or a combination thereof, among other examples of electrically conductive metals.

At the bonding interface 602, the bonding pads 618 of the semiconductor structure 100a and the bonding pads 614 of the semiconductor structure 100b are directly bonded together in metal-to-metal bonds. Moreover, a dielectric layer of the one or more dielectric layers 116 of the semiconductor structure 100a and a dielectric layer of the one or more dielectric layers 610 of the semiconductor structure 100b are directly bonded by dielectric-to-dielectric bonds.

As further shown in FIG. 6, the passivation layer(s) 120-124, the connection pads 126, and the connection structures 128 are located on the back side of the semiconductor structure 100a as opposed to being located above the interconnect layer 104 on the front side of the semiconductor structure 100a (e.g., as illustrated in FIG. 1). To electrically connect the connection pads 126 and the connection structures 128 to the conductive structures 118 in the interconnect layer 104, one or more through-substrate interconnect structures 622 may be included in the semiconductor structure 100a. A through-substrate interconnect structure 622 may extend through the device layer 102 (e.g., through the semiconductor layer 108 of the device layer 102) between a connection pad 126 and a conductive structure 118 on opposing sides of the device layer 102. A through-substrate interconnect structure 622 may include a through substrate via (TSV), a metal pillar, a metal column, and/or another type of vertically elongated conductive structure that extends fully through the device layer 102. A through-substrate interconnect structure 622 may further extend through an STI structure 112 that is included in the front side of the semiconductor layer 108. A through-substrate interconnect structure 622 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material.

One or more liners 624, 626 may be included between the sidewalls of a through-substrate interconnect structure 622 and the semiconductor layer 108. The one or more liners 624, 626 may include adhesion liners, barrier liners, diffusion liners, and/or another type of liners. Moreover, a dielectric layer 628 may be included on the back side of the semiconductor layer 108 between the bottoms of the DTI structures 114 and the passivation layers 120-124.

As indicated above, FIG. 6 is provided as an example. Other examples may differ from what is described with regard to FIG. 6.

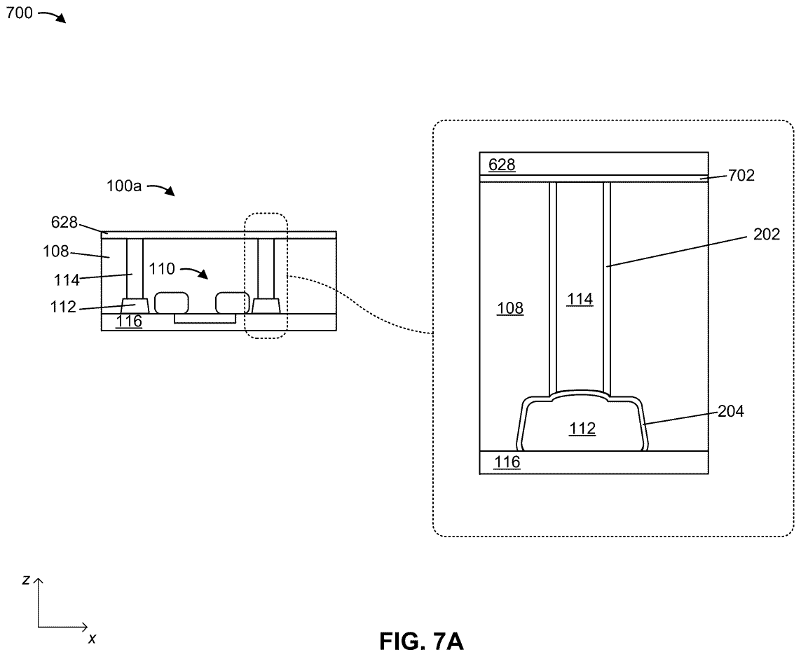

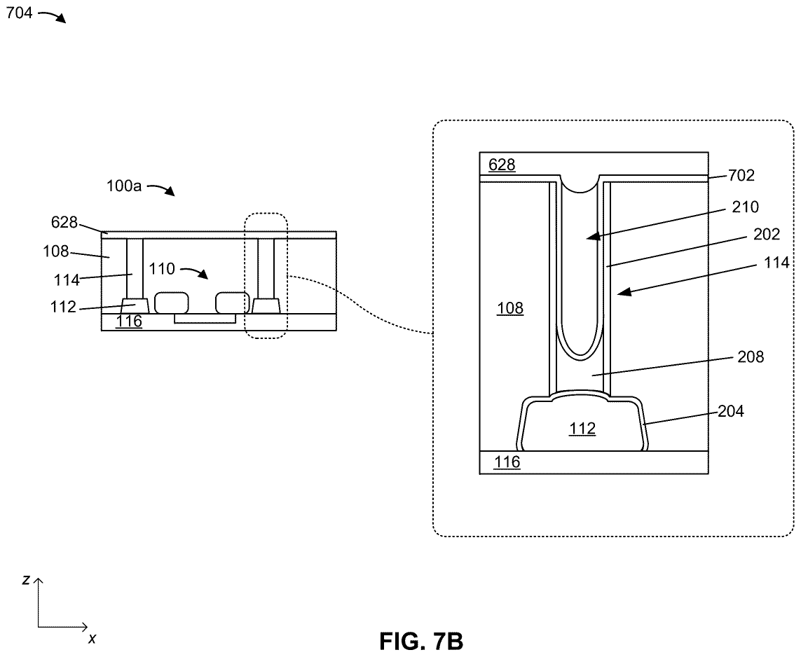

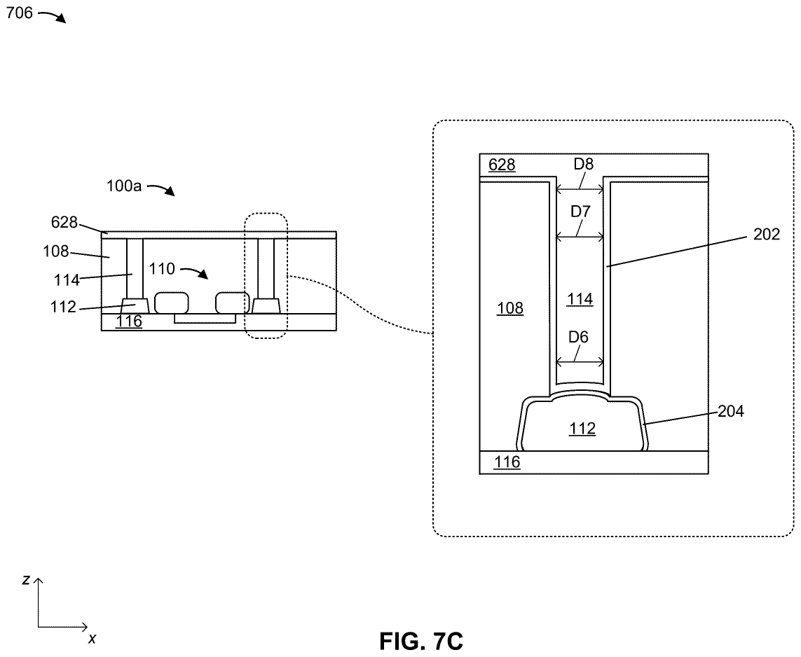

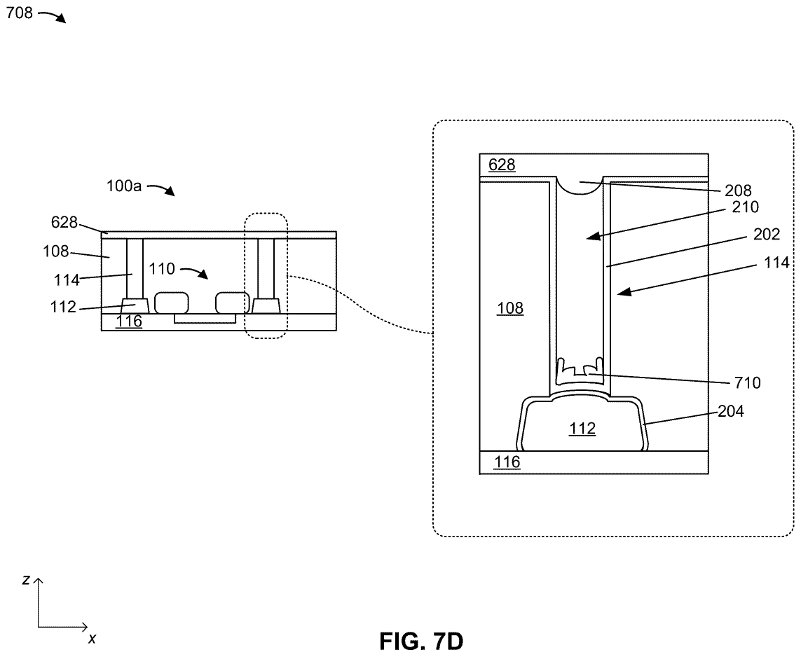

FIGS. 7A-7D are diagrams of example implementations of a DTI structure 114 described herein. The example implementations of DTI structures 114 illustrated in FIGS. 7A-7D may be implemented in the semiconductor device 600 and/or in another semiconductor device.

FIG. 7A illustrates an example implementation 700 of a DTI structure 114. As shown in FIG. 7A, the example implementation 700 of the DTI structure 114 is similar to the example implementation 200 illustrated in FIG. 2A. However, in the example implementation 700, the high-k dielectric liner 202 is omitted from the bottom of the DTI structure 114 (the bottom of the DTI structure 114, and the back side of the semiconductor layer 108, are facing upward in FIG. 7A). Instead, another high-k dielectric liner 702 that is included over the back side of the semiconductor layer 108 is in contact with the bottom of the DTI structure 114. The high-k dielectric liner 702 may be included between the bottom of the DTI structure 114 and the dielectric layer 628 over the back side of the semiconductor layer 108. The high-k dielectric liner 702 may be in contact with ends of the high-k dielectric liner 202 on the sidewalls of the DTI structure 114 so that the combination of the high-k dielectric liners 202, 702 cover the sidewalls and bottom of the DTI structure 114.

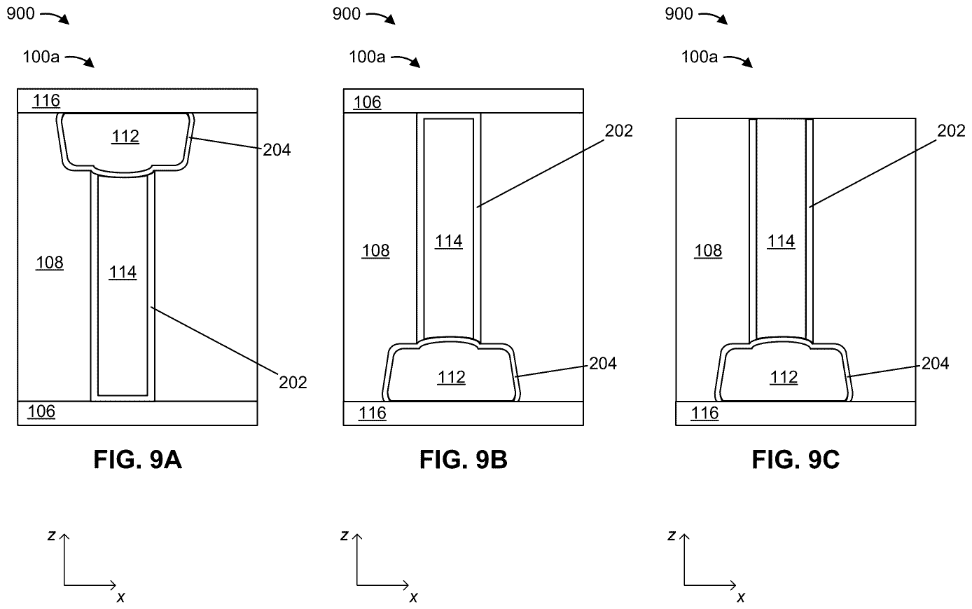

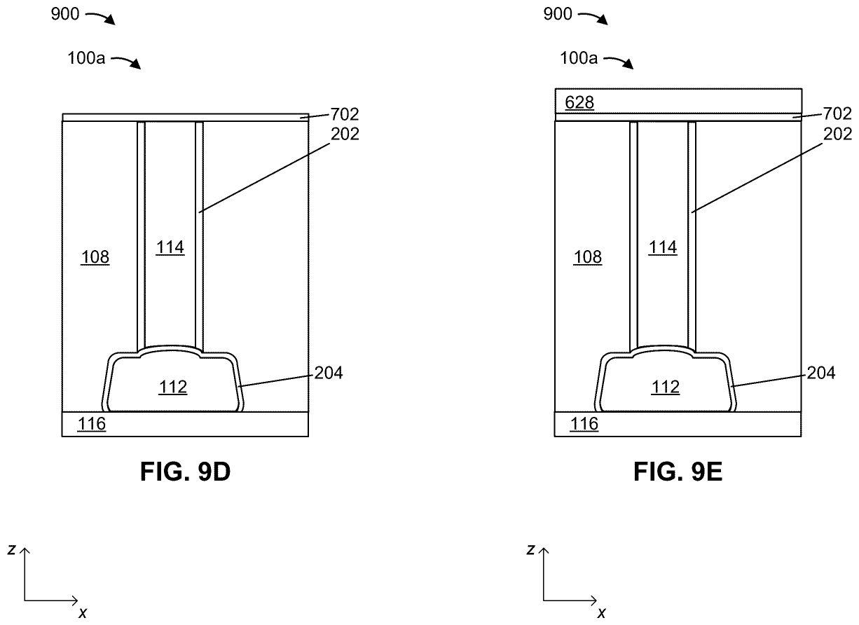

As described in greater detail in connection with FIGS. 9A-9E, the DTI structure 114 and the high-k dielectric liner 202 in the example implementation 700 may be formed from the front side of the semiconductor structure 100a, and the high-k dielectric liner 702 may be formed from the back side of the semiconductor structure 100a. Thus, the high-k dielectric liner 202 is omitted from between the top of the DTI structure 114 (facing downward in FIG. 7A) and the liner(s) 204 between the DTI structure 114 and the STI structure 112.

The high-k dielectric material of the high-k dielectric liner 702 has a dielectric constant that is higher than the dielectric constant of the liner(s) 204 of the STI structure 112. The high-k dielectric material of the high-k dielectric liner 702 may be the same high-k dielectric material of the high-k dielectric liner 202, or the high-k dielectric liners 202, 702 may include different high-k dielectric materials.

In some implementations, the high-k dielectric liner 702 includes a high-k oxide dielectric material having a dielectric constant that is greater than the dielectric constant of silicon nitride (Si₃N₄). For example, the high-k dielectric liner 702 may include a high-k oxide dielectric material having a dielectric constant that is at least approximately 7 to 10 or greater. Examples of such high-k oxide dielectric materials include an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the high-k dielectric liner 702 includes a multiple-layer thin film, where each layer includes a different high-k dielectric material.

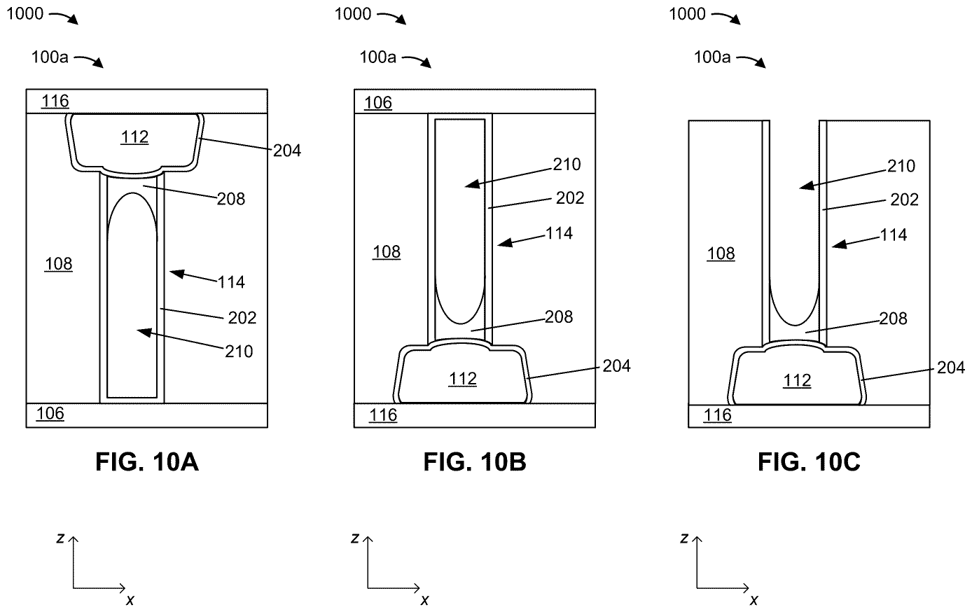

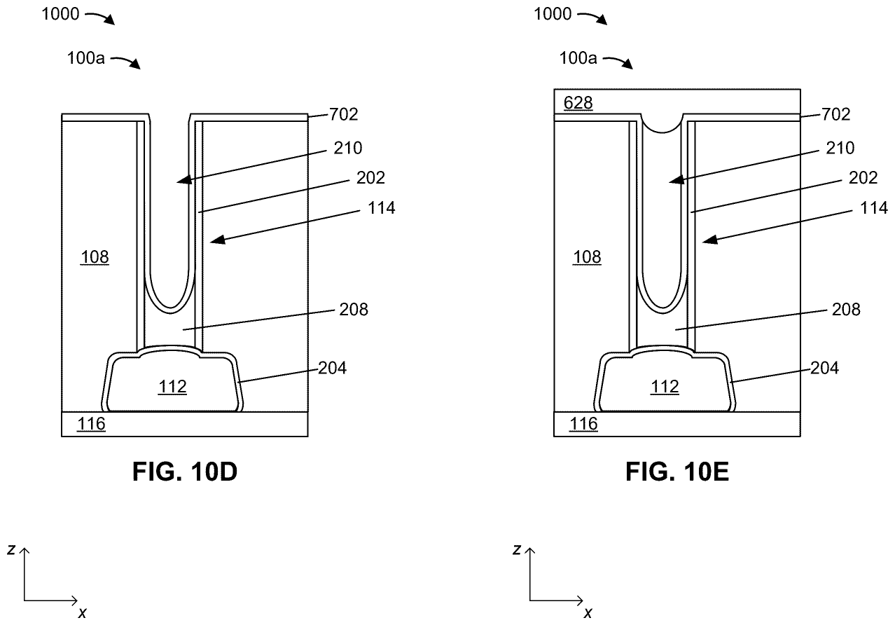

FIG. 7B illustrates an example implementation 704 of a DTI structure 114. As shown in FIG. 7B, the example implementation 704 of the DTI structure 114 is similar to the example implementation 700 in FIG. 7A. However, in the example implementation 704, the DTI structure 114 includes a plug 208 at the top of the DTI structure 114 and an air gap 210 at the bottom of the DTI structure 114. As described in greater detail in connection with FIGS. 10A-10E, the bottom of the DTI structure 114 may be opened during back side processing of the semiconductor structure 100a, which opens up the air gap 210. The high-k dielectric liner 702 may be subsequently formed on the back side of the semiconductor layer 108, resulting in a portion of the high-k dielectric liner 702 being formed on the sidewalls and on the bottom surface of the air gap 210 before the air gap 210 is closed up again by formation of the dielectric layer 628. The sidewalls of the air gap 210 may correspond to portions of the high-k dielectric liner 202, and the bottom surface of the air gap 210 may correspond to the bottom surface of the plug 208. In some implementations, the bottom surface of the dielectric layer 628 that extends into the air gap 210 may have a convex cross-sectional profile, as shown in the example in FIG. 7B.

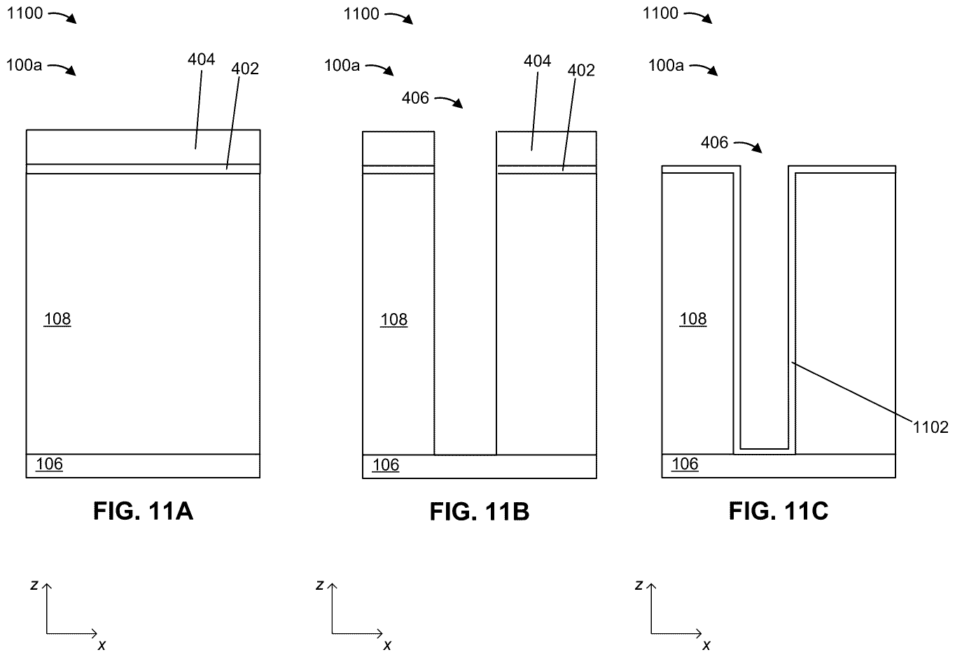

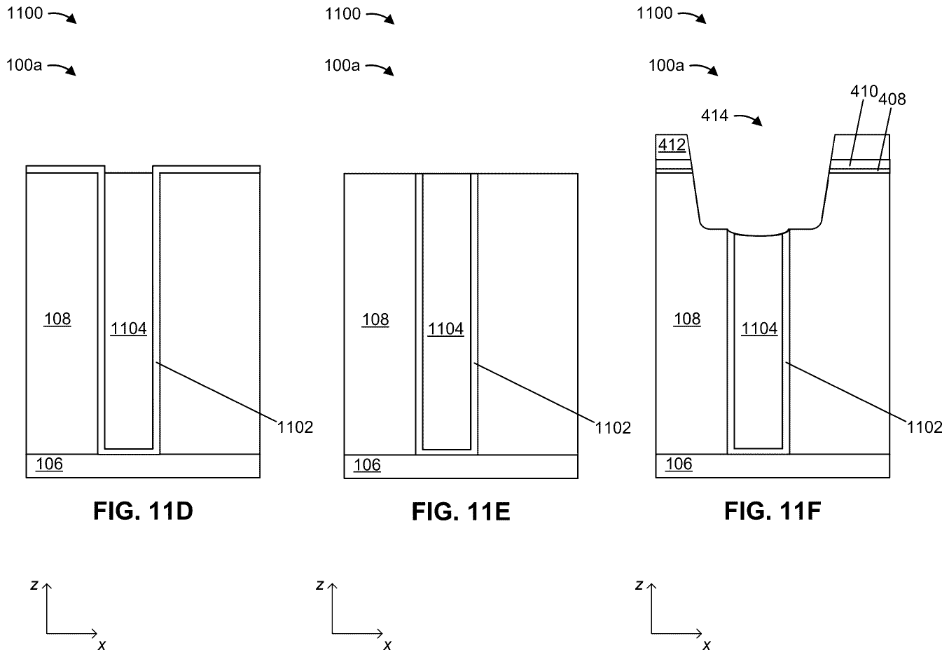

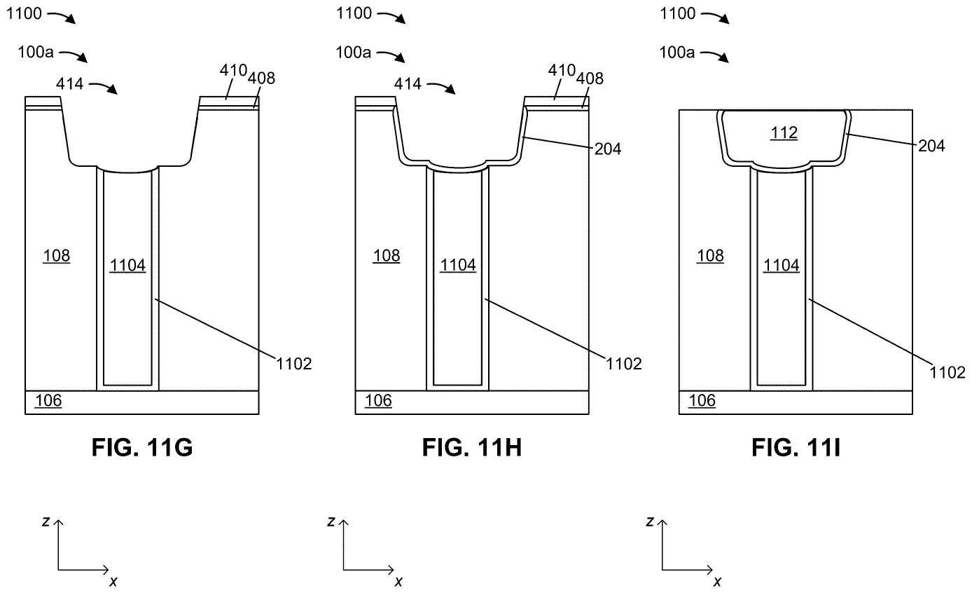

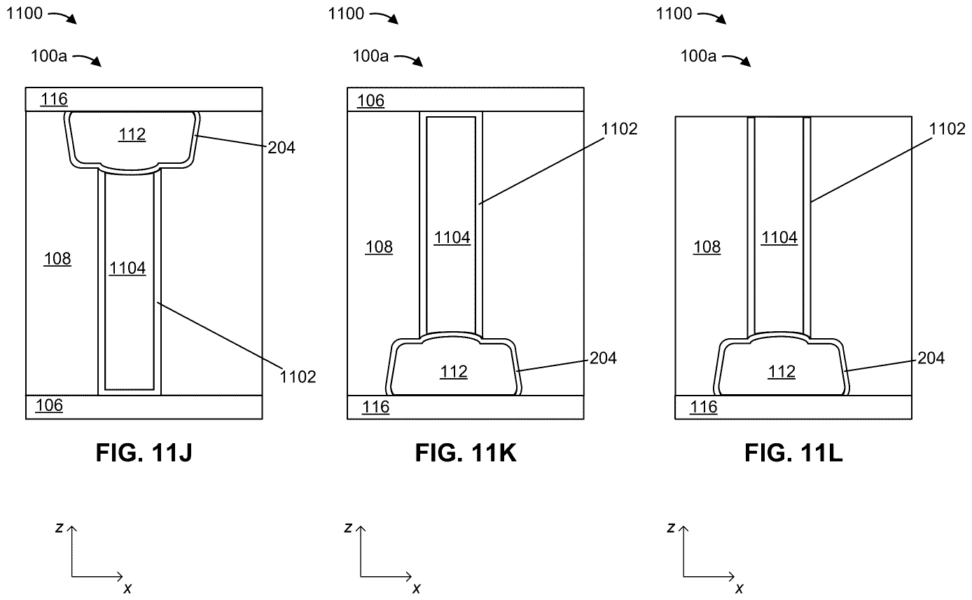

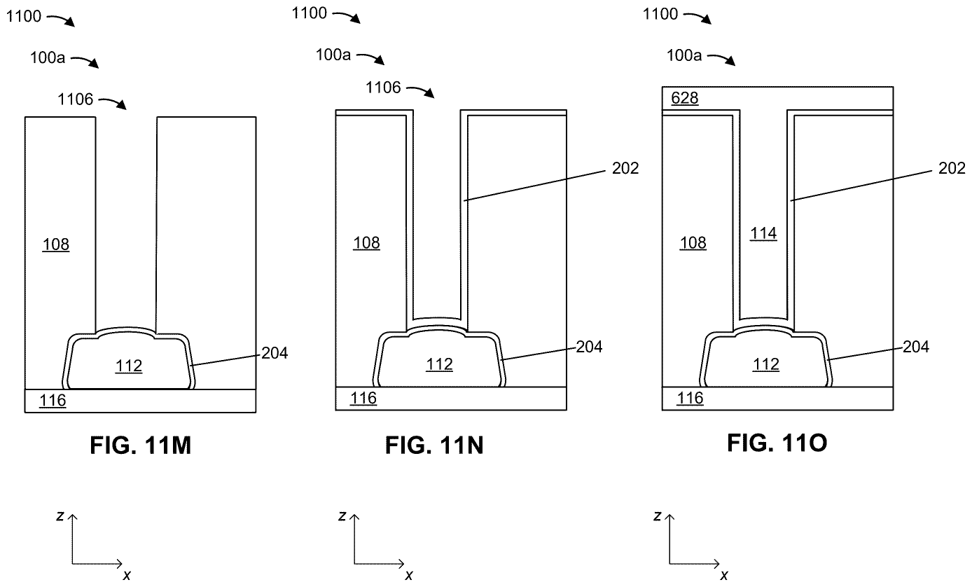

FIG. 7C illustrates an example implementation 706 of a DTI structure 114. As shown in FIG. 7C, the example implementation 706 of the DTI structure 114 is similar to the example implementation 200 illustrated in FIG. 2A. However, in the example implementation 700, the high-k dielectric liner 202 is included between the bottom of the DTI structure 114 (which is facing downward in FIG. 7C) and the STI structure 112, and the high-k dielectric liner 702 may be omitted from between the DTI structure 114 and the dielectric layer 628. As described in greater detail in connection with FIGS. 11A-11O, the DTI structure 114 and the high-k dielectric liner 202 in the example implementation 706 may be formed from the back side of the semiconductor structure 100a. For example, the DTI structure 114 in the example implementation 706 may be a back side DTI (BDTI) structure that provides optical isolation in a pixel sensor array in the semiconductor structure 100a (e.g., in implementations in which the semiconductor device 600 is an image sensor device). This results in the high-k dielectric liner 202 being deposited above the STI structure 112 and the DTI structure 114 being deposited on the high-k dielectric liner 202. The DTI structure 114 may be formed by depositing material of the dielectric layer 628 in a back side recess above the STI structure 112. Thus, the bottom of the DTI structure 114 in the example implementation 706 is facing the STI structure 112, and the top of the DTI structure 114 is facing the back side of the semiconductor layer 108.

As further shown in FIG. 7C, the sidewalls of the DTI structure 114 may be substantially vertical with minimal taper between a bottom and a top of the DTI structure 114. For example, a ratio of widths at the bottom, middle, and top of the DTI structure 114 (respectively indicated in FIG. 7C as dimensions D6, D7, D8) may be approximately 1.0-1.2:1.0-1:2:1.0-1.2. The high verticality of the sidewalls of the DTI structure 114 may be achieved by forming the recess for the DTI structure 114 during front side processing of the semiconductor structure 100a, and this may provide more lateral area for the integrated circuit structures 110 in the semiconductor layer 108. In particular, the recess may be formed prior to formation of photodiodes (e.g., integrated circuit structures 110) of pixel sensors of the pixel sensor array of the semiconductor structure 100a. If the recesses were formed on the back side of the semiconductor layer 108 after formation of the photodiodes, formation of the recess for the DTI structure 114 may be limited to low-energy plasma etching techniques, which may cause a large amount of sidewall taper to occur in the recess. Forming the recess on the front side of the semiconductor layer 108 prior to formation of the photodiodes enables high-energy plasma etching techniques to be used to form the recess in a highly vertical manner without potentially causing damage to the photodiodes (which might otherwise occur if the recesses were formed on the back side of the semiconductor layer 108). Additionally and/or alternatively, damage to the sidewalls and/or bottom of the DTI structure 114 can be recovered by the front end high temperature thermal budget.

As further described in connection with FIGS. 11A-11O, the recess formed in the front side of the semiconductor layer 108 may be filled in with a dummy DTI structure and a dummy liner, these dummy structures may be subsequently replaced from the back side of the semiconductor layer 108 with the DTI structure 114 and the associated high-k dielectric liner 202. This back side formation of the DTI structure 114 and the associated high-k dielectric liner 202 protects subsequent layers and/or structures formed above the front side of the semiconductor layer 108 from being contaminated by the high-k dielectric material(s) of the high-k dielectric liner 202. This provides for greater flexibility in selecting the high-k dielectric material(s) for the high-k dielectric liner 202.

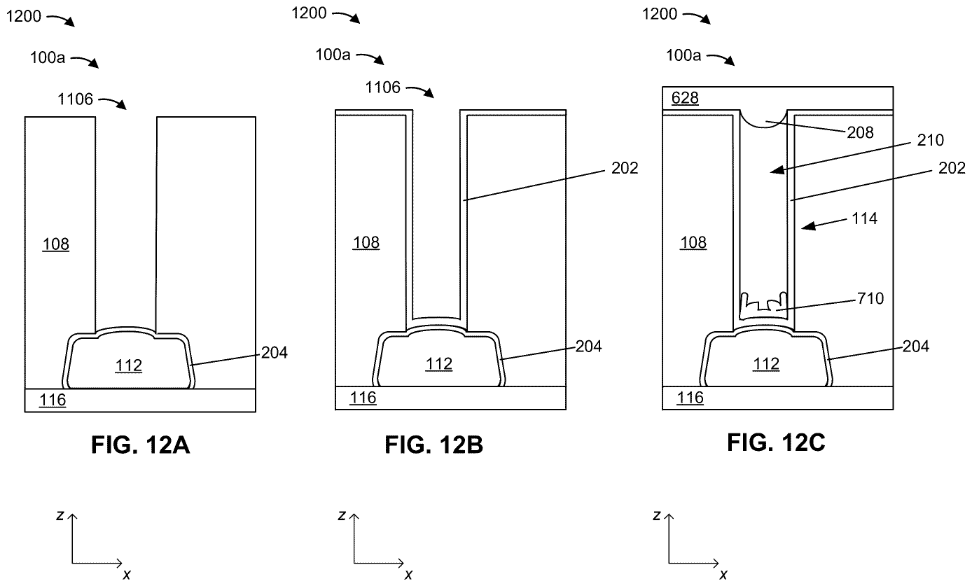

FIG. 7D illustrates an example implementation 708 of a DTI structure 114. As shown in FIG. 7D, the example implementation 708 of the DTI structure 114 is similar to the example implementation 706 in FIG. 7C. However, in the example implementation 708, the DTI structure 114 includes a plug 208 at the top of the DTI structure 114 and an air gap 210 at the bottom and/or at the middle of the DTI structure 114. As described in greater detail in connection with FIGS. 12A-12C, a dummy DTI structure and a dummy liner is removed from the semiconductor layer 108 to form a recess in the semiconductor layer 108 from a back side of the semiconductor layer 108. The high-k dielectric liner 202 may be subsequently formed on the back side of the semiconductor layer 108, and then the dielectric layer 628 is deposited such that the material of the dielectric layer 628 closes up the recess before the recess is fully filled in with the material of the dielectric layer 628. In some implementations, a small amount of dielectric material 710 is deposited in the air gap 210 before the recess is sealed.

As indicated above, FIGS. 7A-7D are provided as examples. Other examples may differ from what is described with regard to FIGS. 7A-7D.

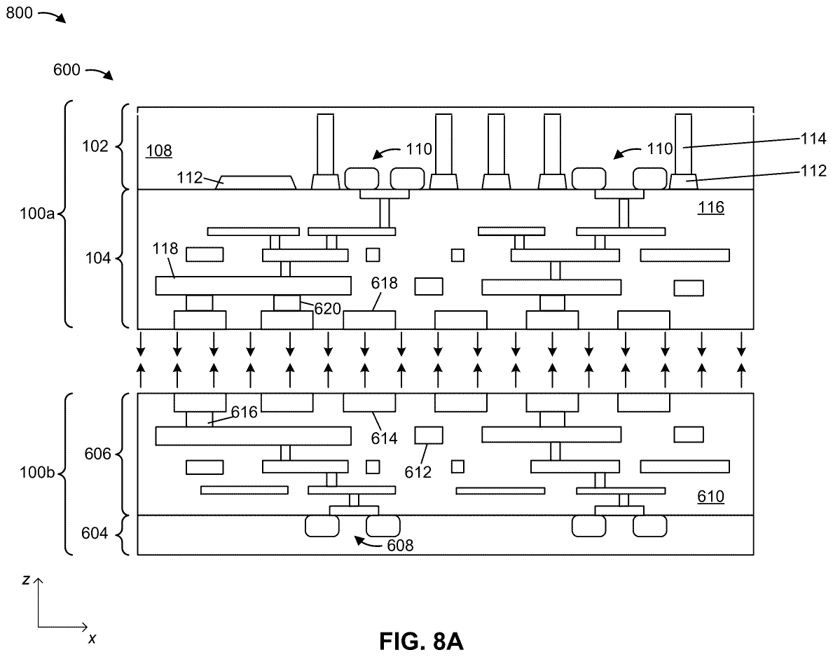

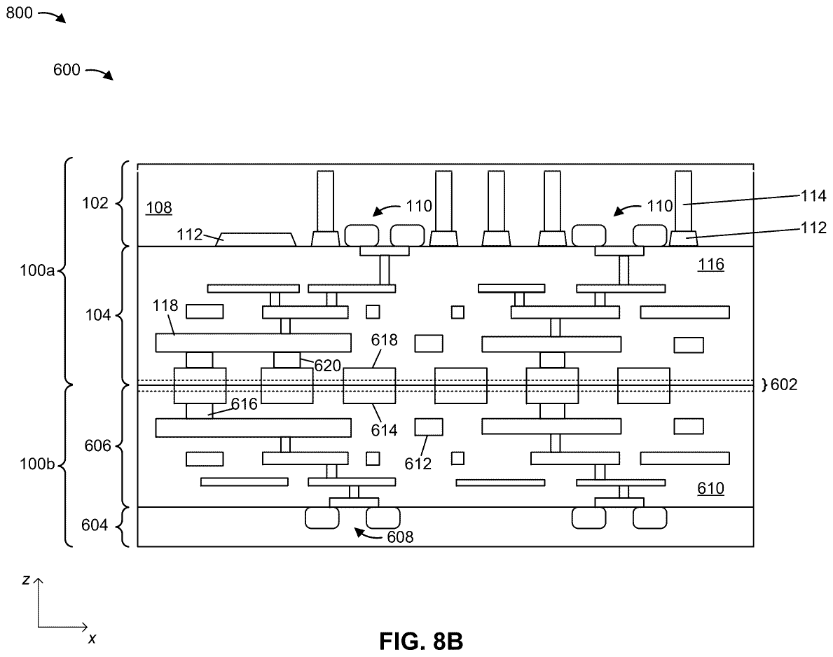

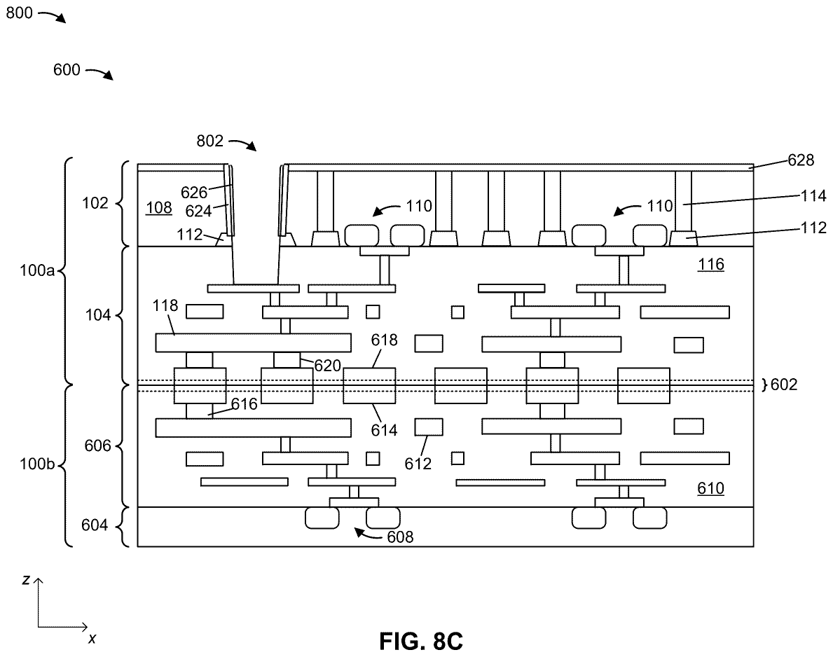

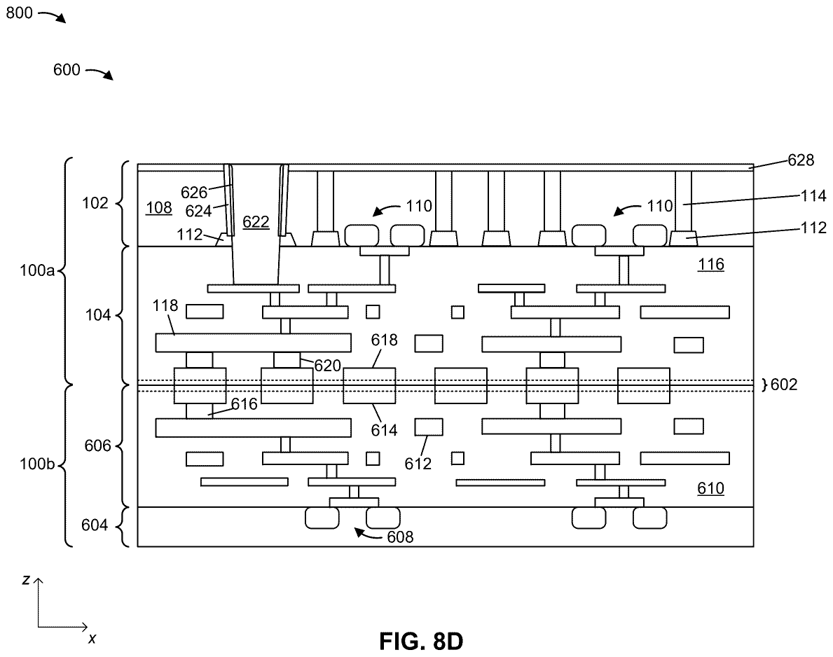

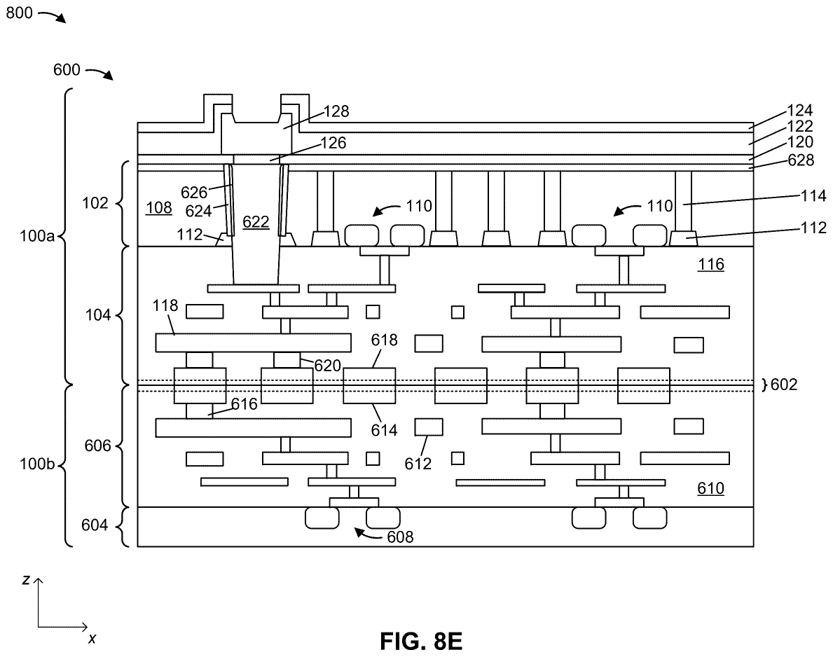

FIGS. 8A-8E are diagrams of an example implementation 800 of forming the semiconductor device 600 (or a portion thereof) described herein. For example, the example implementation 800 may include an example of bonding the semiconductor structures 100a and 100b of the semiconductor device 600, and performing backside processing on the semiconductor structure 100a after bonding. In some implementations, one or more semiconductor processing tools may be used to perform one or more of the operations described in connection with the example implementation 800, such as a deposition tool, an exposure tool, a developer tool, an etch tool, a planarization tool, a bonding tool, and/or another type of semiconductor processing tool. The semiconductor structures 100a and/or 100b may be manufactured by similar processing operations described in connection with FIGS. 3A-3E.

As shown in FIGS. 8A and 8B, a bonding operation is performed to bond the semiconductor structure 100a and the semiconductor structure 100b at the bonding interface 602 such that the semiconductor structure 100a and the semiconductor structure 100b are vertically arranged or stacked (e.g., in the z-direction) in the semiconductor device 600. The semiconductor structure 100a and the semiconductor structure 100b may be vertically arranged or stacked in a wafer on wafer (WoW) configuration, a die on wafer configuration, a die on die configuration, and/or another direct bonding configuration. A bonding tool may be used to perform the bonding operation to bond the semiconductor structure 100a and the semiconductor structure 100b at the bonding interface 602. The bonding operation may include forming a direct bond between the semiconductor structure 100a and the semiconductor structure 100b through a direct physical connection of the bonding pads 618 of the semiconductor structure 100a with the bonding pads 614 of the semiconductor structure 100b, and through a direct physical connection of a dielectric layer 116 of the semiconductor structure 100a with a dielectric layer 610 of the semiconductor structure 100b. In this way, the interconnect layer 104 on the frontside of the semiconductor structure 100a and the interconnect layer 606 on the frontside of the semiconductor structure 100b may be facing each other in the semiconductor device 600.

As shown in FIGS. 8C-8E, backside processing may be performed on the backside of the semiconductor structure 100a after the semiconductor structure 100a and the semiconductor structure 100b are bonded at the bonding interface 602. As shown in FIG. 8C, the backside processing may include using a planarization tool (e.g., a wafer grinding tool) to perform a wafer grinding operation to thin down the device layer 102. Moreover, a deposition tool may be used to deposit the dielectric layer 628 over the back side of the semiconductor layer 108.

As shown in FIGS. 8C and 8D, the backside processing may include forming one or more through-substrate interconnect structures 622 through the semiconductor layer 108 of the device layer 102 of the semiconductor structure 100a such that the one or more through-substrate interconnect structures 622 land on one or more conductive structures 118 in the interconnect layer 104 on the frontside of the semiconductor structure 100a.

As shown in FIG. 8C, to form a through-substrate interconnect structure 622, a recess 802 may be formed through the semiconductor layer 108 from the backside of the device layer 102. The recess 802 may extend through an STI structure 112 in the semiconductor layer 108 and into the dielectric layer(s) 116 in the interconnect layer 104. A conductive structure 118 in the interconnect layer 104 may be exposed through the recess 802.

In some implementations, a pattern in a photoresist layer is used to etch the semiconductor layer 108, the STI structure 112, and/or the dielectric layer 116 to form the recess 802. In these implementations, a deposition tool may be used to form the photoresist layer on the dielectric layer 628 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 628, the semiconductor layer 108, the STI structure 112, and/or the dielectric layer 116 based on the pattern to form the recess 802. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 802 based on a pattern.

As shown in FIG. 8D, a deposition tool may be used to deposit the material of the through-substrate interconnect structure 622 in the recess 802 using a CVD technique, a PVD technique, an ALD technique, an electroplating technique, and/or another suitable deposition technique. The through-substrate interconnect structure 622 may be deposited in one or more deposition operations. In some implementations, a seed layer is first deposited, and the through-substrate interconnect structure 622 is deposited on the seed layer. In some implementations, one or more liners 624, 626 (e.g., adhesion liners, diffusion barrier liners, passivation liners, electrical isolation liners) are deposited in the recess, and then the through-substrate interconnect structure 622 is deposited on the liners(s) 624, 626. In some implementations, a planarization tool is used to perform a planarization operation (e.g., a CMP operation) to planarize the through-substrate interconnect structure 622 after the through-substrate interconnect structure 622 is deposited.

As shown in FIG. 8E, the passivation layers 120-124, the connection pads 126, and the connection structures 128 may be formed in a similar manner as described in connection with FIG. 3E, except that the passivation layers 120-124, the connection pads 126, and the connection structures 128 are formed over the back side of the semiconductor layer 108 as opposed to being formed over the interconnect layer 104.

As indicated above, FIGS. 8A-8E are provided as an example. Other examples may differ from what is described with regard to FIGS. 8A-8E.

FIGS. 9A-9E are diagrams of an example implementation 900 of forming a semiconductor device described herein. In some implementations, the example implementation 900 includes an example process for forming the example implementation 700 of the STI structure 112 and the DTI structure 114 illustrated in FIG. 7A. In some implementations, one or more of the operations described in connection with the example implementation 900 may be performed to form an STI structure 112 and a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 900, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 9A, a similar combination of operations as illustrated and described in connection with FIGS. 4A-4I for the example implementation 400 may be performed to form the DTI structure 114, the high-k dielectric liner 202, the STI structure 112, and the liner(s) 204 form the front side of the semiconductor layer 108 prior to bonding the semiconductor structures 100a and 100b.

As shown in FIG. 9B, the semiconductor structure 100a may be flipped and bonded to the semiconductor structure 100b (e.g., after forming the DTI structure 114, the high-k dielectric liner 202, the STI structure 112, and the liner(s) 204).

As shown in FIG. 9C, backside processing may be performed on the semiconductor structure 100a after bonding the semiconductor structures 100a and 100b, including using a planarization tool (e.g., a wafer grinding tool) to perform a wafer grinding operation to thin down the device layer 102. In some implementations, the wafer grinding operation results in removal of the semiconductor layer 106 of the device layer 102 and a portion of the semiconductor layer 108. The bottom of the DTI structure 114 may be exposed on the back side of the semiconductor structure 100a after the wafer grinding operation.

As shown in FIG. 9D, the high-k dielectric liner 702 may be formed over and/or on the back side of the semiconductor layer 108 such that a portion of the high-k dielectric liner 702 is formed on the exposed bottom of the DTI structure 114. A deposition tool may be used to deposit the material of the high-k dielectric liner 702 using a PVD technique, an ALD technique, a CVD technique, an oxidation technique, and/or another suitable deposition technique. In some implementations, a planarization tool may be used to perform a planarization operation (e.g., a CMP operation) to planarize the high-k dielectric liner 702 after the high-k dielectric liner 702 is deposited.

As shown in FIG. 9E, the dielectric layer 628 may be formed over the back side of the semiconductor layer 108 such that the dielectric layer 628 is formed over and/or on the high-k dielectric liner 702. A deposition tool may be used to deposit the material of the dielectric layer 628 using a PVD technique, an ALD technique, a CVD technique, an oxidation technique, and/or another suitable deposition technique. In some implementations, a planarization tool may be used to perform a planarization operation (e.g., a CMP operation) to planarize the dielectric layer 628 after the dielectric layer 628 is deposited.

As indicated above, FIGS. 9A-9E are provided as an example. Other examples may differ from what is described with regard to FIGS. 9A-9E.

FIGS. 10A-10E are diagrams of an example implementation 1000 of forming a semiconductor device described herein. In some implementations, the example implementation 1000 includes an example process for forming the example implementation 704 of the STI structure 112 and the DTI structure 114 illustrated in FIG. 7B. In some implementations, one or more of the operations described in connection with the example implementation 1000 may be performed to form an STI structure 112 and a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 1000, such as a deposition tool, an exposure tool, a developer tool, an etch tool, a planarization tool, a plating tool, an ion implantation tool, an annealing tool, a bonding tool, and/or another type of semiconductor processing tool.

As shown in FIG. 10A, a similar combination of operations as illustrated and described in connection with FIGS. 5A-5I for the example implementation 500 may be performed to form the DTI structure 114, the high-k dielectric liner 202, the STI structure 112, and the liner(s) 204 form the front side of the semiconductor layer 108 prior to bonding the semiconductor structures 100a and 100b. However, instead of fully filling in the recess 406 with the material of the DTI structure 114 (e.g., as in the example implementation 400), material of a plug 208 is deposited at a high deposition rate to cause the material of the plug 208 to seal the top of the recess 406 before the recess 406 is fully filled in with material. This results in the unfilled volume within the recess 406 corresponding to an air gap 210 of the DTI structure 114.

As shown in FIG. 10B, the semiconductor structure 100a may be flipped and bonded to the semiconductor structure 100b (e.g., after forming the DTI structure 114, the high-k dielectric liner 202, the STI structure 112, and the liner(s) 204).

As shown in FIG. 10C, backside processing may be performed on the semiconductor structure 100a after bonding the semiconductor structures 100a and 100b, including using a planarization tool (e.g., a wafer grinding tool) to perform a wafer grinding operation to thin down the device layer 102. In some implementations, the wafer grinding operation results in removal of the semiconductor layer 106 of the device layer 102 and a portion of the semiconductor layer 108. As further shown in FIG. 10C, the wafer grinding operation results in the bottom of the air gap 210 of the DTI structure 114 being opened through the back side of the semiconductor structure 100a.

As shown in FIG. 10D, the high-k dielectric liner 702 may be formed over and/or on the back side of the semiconductor layer 108 in a similar manner as described in connection with FIG. 9D. However, in the example implementation 1000, a portion of the high-k dielectric liner 702 is formed on the sidewalls and on the bottom surface of the air gap 210 (e.g., which is facing downward in FIG. 10D) of the DTI structure 114.

As shown in FIG. 10E, the dielectric layer 628 may be formed over the back side of the semiconductor layer 108 such that the dielectric layer 628 is formed over and/or on the high-k dielectric liner 702. The material of the dielectric layer 628 may be deposited at a high deposition rate to cause the material of the dielectric layer 628 to seal the bottom of the air gap 210 before the air gap 210 is fully filled in with material. A deposition tool may be used to deposit the material of the dielectric layer 628 using a deposition technique that has low step coverage performance. In other words, the deposition technique that is used to deposit the material of the dielectric layer 628 may result in deposited material accumulating at a faster rate at the bottom of the air gap 210 (e.g., which is facing upward in FIG. 10E) and on the back side of the semiconductor layer 108 than at the top of the air gap 210 (e.g., which is facing downward in FIG. 10E). Examples of such deposition techniques may include atmospheric pressure CVD, LPCVD, and/or sputtering (e.g., PVD), among other examples.

As indicated above, FIGS. 10A-10E are provided as an example. Other examples may differ from what is described with regard to FIGS. 10A-10E.

FIGS. 11A-11O are diagrams of an example implementation 1100 of forming a semiconductor device described herein. In some implementations, the example implementation 1100 includes an example process for forming the example implementation 706 of the STI structure 112 and the DTI structure 114 illustrated in FIG. 7C. In some implementations, one or more of the operations described in connection with the example implementation 1100 may be performed to form an STI structure 112 and a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 1100, such as a deposition tool, an exposure tool, a developer tool, an etch tool, a planarization tool, a plating tool, an ion implantation tool, an annealing tool, a bonding tool, and/or another type of semiconductor processing tool.

As shown in FIGS. 11A-11I, the example implementation 1100 includes a similar combination of operations as illustrated and described in connection with FIGS. 4A-4I for the example implementation 400. However, instead of forming the high-k dielectric liner 202 and the DTI structure 114 in the recess 406 from the front side of the device layer 102 (e.g., as in the example implementation 400), a dummy liner 1102 and a dummy DTI structure 1104 are formed in the recess 406 from the front side of the device layer 102 in the example implementation 1100. The STI structure 112 and the associated liner(s) 204 are then formed on the dummy liner 1102 and on the dummy DTI structure 1104.

The dummy liner 1102 and a dummy DTI structure 1104 may be formed in the recess 406 as placeholders for the high-k dielectric liner 202 and the DTI structure 114. The dummy liner 1102 and a dummy DTI structure 1104 enable the recess 406 to be formed during front side processing of the semiconductor structure 100a. This enables high-energy plasma etch techniques may be used to form the recess 406 without causing damage to photodiodes and other structures that are to be formed in the semiconductor layer 108 after formation of the recess 406.

The dummy liner 1102 and a dummy DTI structure 1104 may each include dielectric materials such as silicon oxide (SiOₓ) and/or silicon nitride (SiₓN_{y}), among other examples. Additionally and/or alternatively, the dummy DTI structure 1104 may include polysilicon material.

A deposition tool may be used to deposit the material of the dummy liner 1102 using a conformal deposition technique such as CVD and/or ALD, among other examples. A deposition tool may be used to deposit the material of the dummy DTI structure 1104 using a CVD technique, a PVD technique, an ALD technique, and/or another suitable deposition technique.

As shown in FIG. 11J, the dielectric layers(s) 116 and the conductive structures 118 (not shown) may be formed over the front side of the semiconductor layer 108 (e.g., after formation of the dummy DTI structure 1104 and the STI structure 112).

As shown in FIG. 11K, the semiconductor structure 100a may be flipped and bonded to the semiconductor structure 100b (e.g., after forming the dummy liner 1102, the dummy DTI structure 1104, the STI structure 112, and the liner(s) 204).

As shown in FIG. 11L, backside processing may be performed on the semiconductor structure 100a after bonding the semiconductor structures 100a and 100b, including using a planarization tool (e.g., a wafer grinding tool) to perform a wafer grinding operation to thin down the device layer 102. In some implementations, the wafer grinding operation results in removal of the semiconductor layer 106 of the device layer 102 and a portion of the semiconductor layer 108. The bottom of the DTI structure 114 may be exposed on the back side of the semiconductor structure 100a after the wafer grinding operation.

As shown in FIG. 11M, an etch tool may be used to perform one or more etch operations to remove the dummy liner 1102 and the dummy DTI structure 1104 from the semiconductor layer 108. The one or more etch operations may be performed from the back side of the semiconductor layer 108 such that removal of the dummy liner 1102 and the dummy DTI structure 1104 results in formation of a recess 1106 that extends into the semiconductor layer 108 from the back side of the semiconductor layer 108. The recess 1106 may be located over the underlying STI structure 112. The recess 1106 may correspond to at least a portion of the recess 406 that was formed on the front side of the semiconductor layer 108. The one or more etch operations may include one or more wet etch operations, one or more gas-based etch operations, and/or another suitable etch operation.

As shown in FIG. 11N, the high-k dielectric liner 202 may be formed over and/or on the back side of the semiconductor layer 108 and in the recess 1106. A deposition tool may be used to perform a conformal deposition operation such as CVD and/or ALD to form the high-k dielectric liner 202 on the sidewalls and on the bottom surface of the recess 1106. The bottom surface of the recess 1106 may correspond to the liner(s) 204 on the bottom of the STI structure 112. Accordingly, the high-k dielectric liner 202 may be formed on a portion of the liner(s) 204 at the bottom of the recess 1106.

As shown in FIG. 11O, the dielectric layer 628 may be formed over the back side of the semiconductor layer 108 such that the dielectric layer 628 is formed over and/or on the high-k dielectric liner 202. The material of the dielectric layer 628 may fill in the remaining area of the recess 1106. The material of the dielectric layer 628 deposited in the recess 1106 may correspond to the DTI structure 114. A deposition tool may be used to deposit the material of the dielectric layer 628 and the DTI structure 114 using a PVD technique, an ALD technique, a CVD technique, an oxidation technique, and/or another suitable deposition technique. In some implementations, a planarization tool may be used to perform a planarization operation (e.g., a CMP operation) to planarize the dielectric layer 628 after the dielectric layer 628 is deposited.

In this way, the recess 406 may be formed on the front side of the semiconductor structure 100a using high-energy plasma-based etch techniques and then filled in with dummy structures. The dummy structures (e.g., the dummy liner 1102, the dummy DTI structure 1104) enable subsequent processes to be performed to form the interconnect layer 104 and to bond the semiconductor structure 100a to the semiconductor structure 100b. The dummy structures may be subsequently removed to reveal the recess 406 (which may correspond to the recess 1106 that is opened from the back side of the semiconductor structure 100a) so that the high-k dielectric liner 202 and the DTI structure 114 may be formed in place of the dummy structures.

As indicated above, FIGS. 11A-11O are provided as an example. Other examples may differ from what is described with regard to FIGS. 11A-11O.

FIGS. 12A-12C are diagrams of an example implementation 1200 of forming a semiconductor device described herein. In some implementations, the example implementation 1200 includes an example process for forming the example implementation 708 of the STI structure 112 and the DTI structure 114 illustrated in FIG. 7D. In some implementations, one or more of the operations described in connection with the example implementation 1200 may be performed to form an STI structure 112 and a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 1200, such as a deposition tool, an exposure tool, a developer tool, an etch tool, a planarization tool, a plating tool, an ion implantation tool, an annealing tool, a bonding tool, and/or another type of semiconductor processing tool.

As shown in FIGS. 12A-12C, a similar combination of operations as illustrated and described in connection with FIGS. 11A-11O for the example implementation 1100 may be performed to form the DTI structure 114 and the high-k dielectric liner 202 from the back side of the semiconductor layer 108 after bonding the semiconductor structures 100a and 100b. The dummy liner 1102 and the dummy DTI structure 1104 may be formed in the recess 406 (e.g., the front side recess) and subsequently removed after bonding the semiconductor structures 100a and 100b to form the recess 1106 (e.g., the back side recess), as shown in FIG. 12A.

As shown in FIG. 12B, the high-k dielectric liner 202 may be formed in the recess 1106 from the back side of the semiconductor layer 108 in a similar manner as described in connection with FIG. 11N.

However, instead of fully filling in the recess 1106 with the material of the dielectric layer 628 to form the DTI structure 114 (e.g., as in FIG. 11O in the example implementation 1100), the material of the dielectric layer 628 is deposited at a high deposition rate to cause the material to form a plug 208 that seals the top of the recess 1106 before the recess 1106 is fully filled in with material. This results in the unfilled volume within the recess 1106 corresponding to an air gap 210 of the DTI structure 114.

As indicated above, FIGS. 12A-12C are provided as an example. Other examples may differ from what is described with regard to FIGS. 12A-12C.

FIG. 13 is a diagram of an example semiconductor device 1300 described herein. FIG. 13 illustrates a cross-section view of the semiconductor device 1300. As shown in FIG. 13, the semiconductor device 1300 is similar to the semiconductor device 600, and includes a similar combination and arrangement of layers and structures as the semiconductor device 600.

However, in the semiconductor device 1300, the DTI structures 114 in the device layer 102 of the semiconductor structure 100a are spaced apart from the dielectric layer 628 on the back side of device layer 102 by a portion of the semiconductor layer 108. The portion of the semiconductor layer 108 may remain between the DTI structures 114 in the device layer 102 of the semiconductor structure 100a and the dielectric layer 628 on the back side of device layer 102 in the semiconductor device 1300 due to differences in processes that were used to form the semiconductor device 1300 and the semiconductor device 600.

For example, and as described in connection with FIG. 8C, a wafer grinding operation is performed to remove material of the semiconductor layer 108 to thin down the semiconductor layer 108. The wafer grinding operation is performed for the semiconductor device 600 at least until the DTI structures 114 (or the dummy DTI structures 1104) are exposed on the back side of the semiconductor layer 108.

However, for the semiconductor device 1300, the wafer grinding operation is stopped prior to the DTI structures 114 being exposed on the back side of the semiconductor layer 108. Thus, in the semiconductor device 1300 the z-direction thickness of the semiconductor layer 108 after the wafer grinding operation is greater than a combined height of an STI structure 112 and a DTI structure 114 in the semiconductor layer 108.

As indicated above, FIG. 13 is provided as an example. Other examples may differ from what is described with regard to FIG. 13.

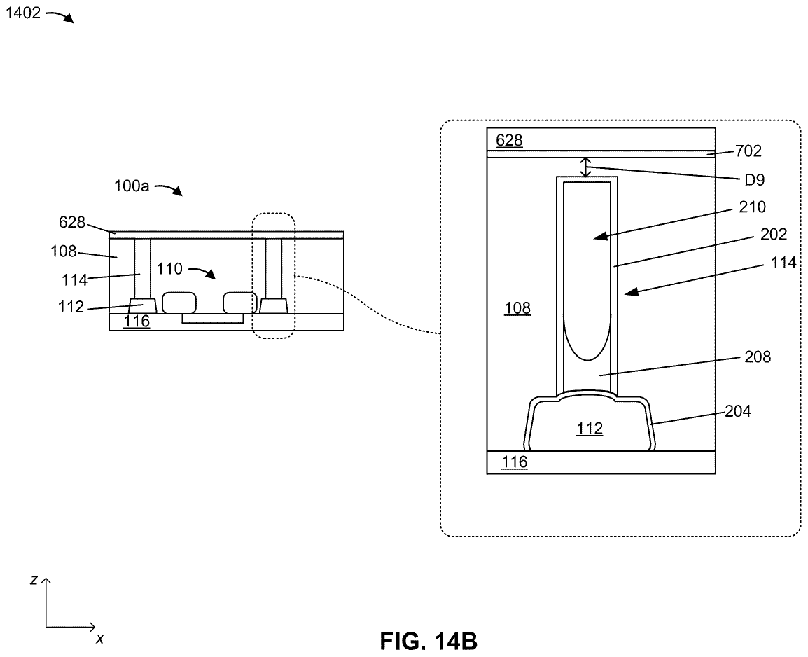

FIGS. 14A and 14B are diagrams of example implementations of a DTI structure 114 described herein. The example implementations of DTI structures 114 illustrated in FIGS. 14A and 14B may be implemented in the semiconductor device 1300 and/or in another semiconductor device.

FIG. 14A illustrates an example implementation 1400 of a DTI structure 114. As shown in FIG. 14A, the example implementation 1400 of the DTI structure 114 is similar to the example implementation 200 illustrated in FIG. 2A. However, in the example implementation 1400, the portion of the high-k dielectric liner 202 vertically adjacent to the bottom of the DTI structure 114 is spaced apart from a back side surface of the semiconductor layer 108 by a distance (indicated in FIG. 14A as a dimension D9). A portion of the semiconductor layer 108 is located vertically between the portion of the high-k dielectric liner 202 vertically adjacent to the bottom of the DTI structure 114 and the high-k dielectric liner 702 over the back side surface of the semiconductor layer 108.

FIG. 14B illustrates an example implementation 1402 of a DTI structure 114. As shown in FIG. 14B, the example implementation 1402 of the DTI structure 114 is similar to the example implementation 206 illustrated in FIG. 2B. However, in the example implementation 1402, the portion of the high-k dielectric liner 202 vertically adjacent to the bottom of the air gap 210 of the DTI structure 114 is spaced apart from a back side surface of the semiconductor layer 108 by a distance (indicated in FIG. 14B as a dimension D9). A portion of the semiconductor layer 108 is located vertically between the portion of the high-k dielectric liner 202 vertically adjacent to the air gap 210 of the bottom of the DTI structure 114 and the high-k dielectric liner 702 over the back side surface of the semiconductor layer 108.

As indicated above, FIGS. 14A and 14B are provided as examples. Other examples may differ from what is described with regard to FIGS. 14A and 14B.

FIG. 15 is a diagram of an example semiconductor device 1500 described herein. FIG. 15 illustrates a cross-section view of the semiconductor device 1500. As shown in FIG. 15, the semiconductor device 1500 is similar to the semiconductor device 600, and includes a similar combination and arrangement of layers and structures as the semiconductor device 600.

However, in the semiconductor device 1500, the STI structures 112 that are vertically adjacent to the DTI structures 114 in the device layer 102 of the semiconductor structure 100a in the semiconductor device 600 are omitted from the semiconductor device 1500. Instead, the DTI structures 114 fully span the vertical (z-direction) distance between the front side surface and the back side surface of the semiconductor layer 108 of the semiconductor structure 100a in the semiconductor device 1500. The semiconductor device 1500 may be formed using similar processing techniques described in connection with FIGS. 8A-8E, except that formation of the STI structures 112 and associated liner(s) 204 above the DTI structures 114 is omitted. This may enable the semiconductor device 1500 to be formed by fewer semiconductor processing operations.

As indicated above, FIG. 15 is provided as an example. Other examples may differ from what is described with regard to FIG. 15.

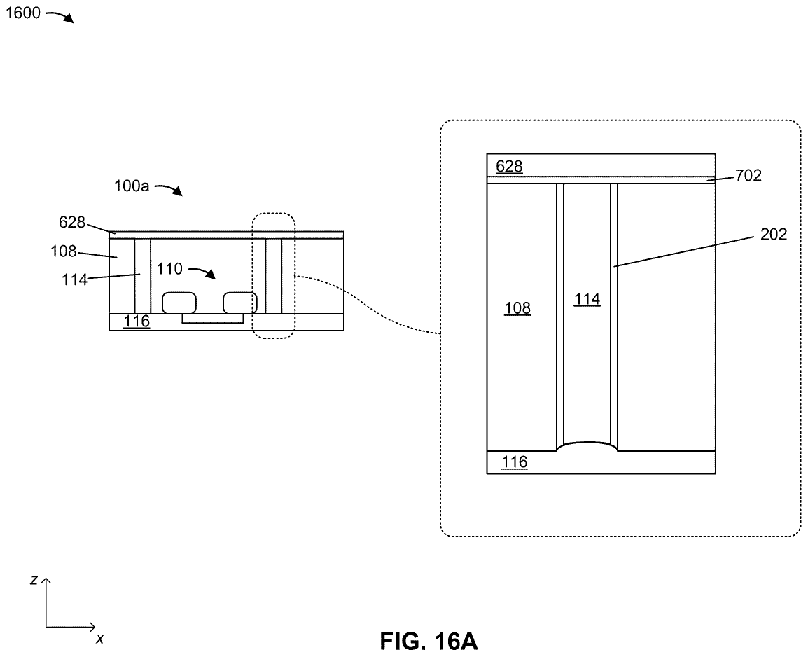

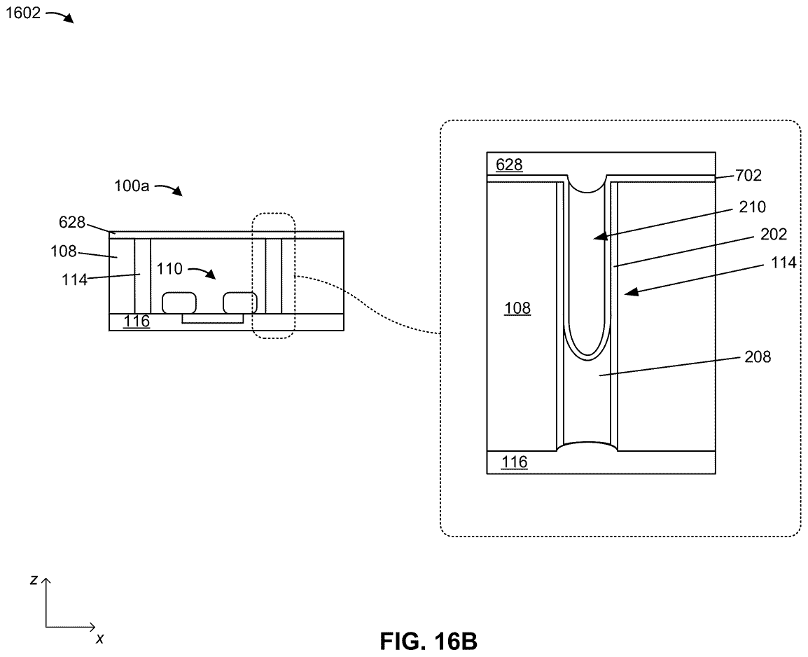

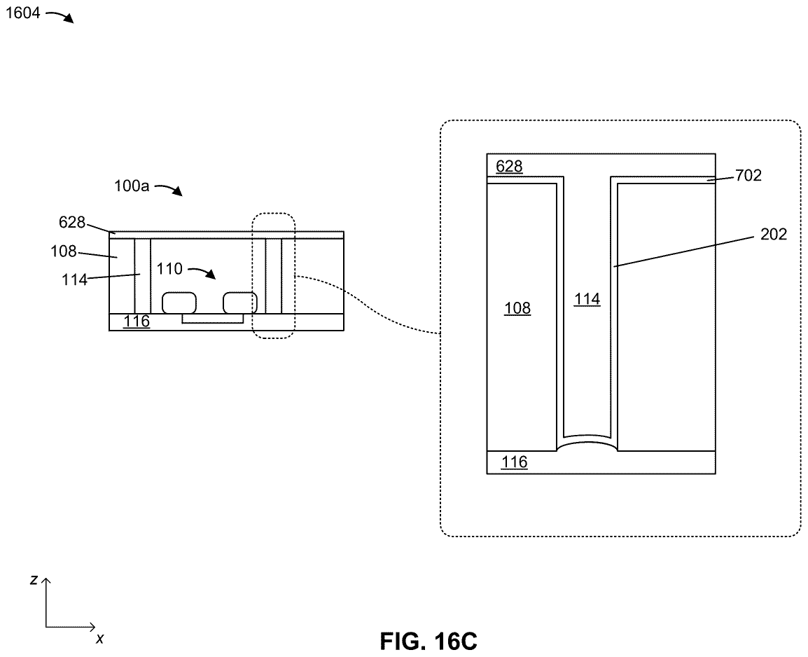

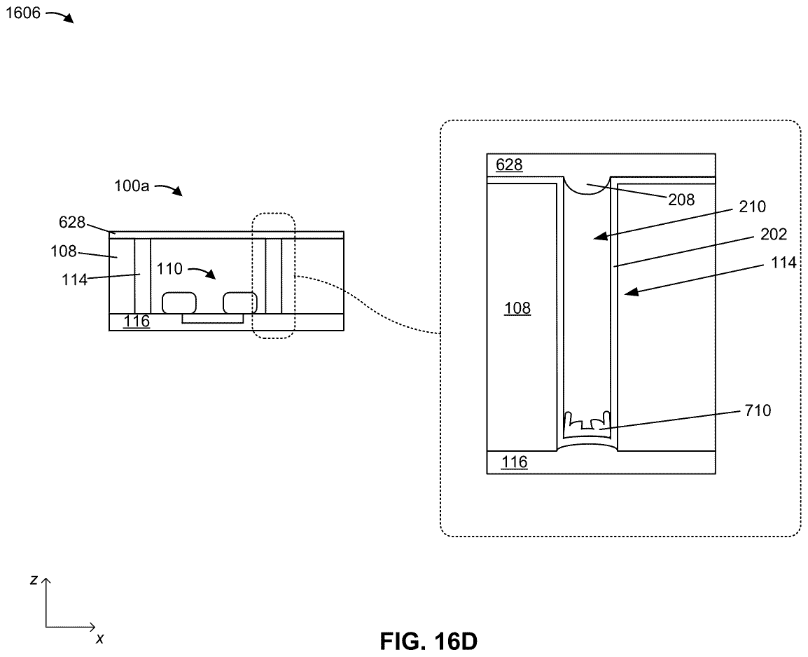

FIGS. 16A-16D are diagrams of example implementations of a DTI structure 114 described herein. The example implementations of DTI structures 114 illustrated in FIGS. 16A-16D may be implemented in the semiconductor device 1500 and/or in another semiconductor device.

FIG. 16A illustrates an example implementation 1600 of a DTI structure 114. As shown in FIG. 16A, the example implementation 1600 of the DTI structure 114 is similar to the example implementation 700 illustrated in FIG. 7A. However, in the example implementation 1600, the DTI structure 114 extends fully between the front side surface and the back side surface of the semiconductor layer 108. Thus, a first end (e.g., a top end) of the DTI structure 114 may be in contact with a dielectric layer 116 in the interconnect layer 104 on the front side of the device layer 102, and a second end (e.g., a bottom end) of the DTI structure 114 may be in contact with the high-k dielectric liner 702 over the back side surface of the semiconductor layer 108. The high-k dielectric liner 202 may fully extend between the front side surface and the back side surface of the semiconductor layer 108 in a similar manner.

The example implementation 1600 of the DTI structure 114 and the high-k dielectric liner 202 may be formed by similar processes illustrated and described in connection with FIGS. 4A-4I and 9A-9E. However, the process operations for forming the STI structure 112 and the associated liner(s) 204 (illustrated in FIGS. 4F-4I) may be omitted. Thus, the DTI structure 114 and the high-k dielectric liner 202 may be formed from the front side of the semiconductor layer 108, and the high-k dielectric liner 702 may be formed from the back side of the semiconductor layer 108.

FIG. 16B illustrates an example implementation 1602 of a DTI structure 114. As shown in FIG. 16B, the example implementation 1602 of the DTI structure 114 is similar to the example implementation 704 illustrated in FIG. 7B. However, in the example implementation 1602, the DTI structure 114 extends fully between the front side surface and the back side surface of the semiconductor layer 108. Thus, a first end (e.g., a plug 208) of the DTI structure 114 may be in contact with a dielectric layer 116 in the interconnect layer 104 on the front side of the device layer 102, and a second end (e.g., an air gap 210) of the DTI structure 114 may be in contact with the dielectric layer 628 over the back side surface of the semiconductor layer 108. The high-k dielectric liner 702 may extend into the air gap 210 between the plug 208 and the dielectric layer 628.

The example implementation 1602 of the DTI structure 114 and the high-k dielectric liner 202 may be formed by similar processes illustrated and described in connection with FIGS. 5A-5I and 10A-10E. However, the process operations for forming the STI structure 112 and the associated liner(s) 204 (illustrated in FIGS. 5F-5I) may be omitted. Thus, the DTI structure 114 and the high-k dielectric liner 202 may be formed from the front side of the semiconductor layer 108, and the high-k dielectric liner 702 may be formed from the back side of the semiconductor layer 108.

FIG. 16C illustrates an example implementation 1604 of a DTI structure 114. As shown in FIG. 16C, the example implementation 1604 of the DTI structure 114 is similar to the example implementation 706 illustrated in FIG. 7C. However, in the example implementation 1604, the DTI structure 114 extends fully between the front side surface and the back side surface of the semiconductor layer 108. Thus, a portion of the high-k dielectric liner 202 at a first end (e.g., a bottom end) of the DTI structure 114 may be in contact with a dielectric layer 116 in the interconnect layer 104 on the front side of the device layer 102, and a second end (e.g., a top end) of the DTI structure 114 may be in contact with the dielectric layer 628 over the back side surface of the semiconductor layer 108.

The example implementation 1604 of the DTI structure 114 and the high-k dielectric liner 202 may be formed by similar processes illustrated and described in connection with FIGS. 11A-11O. However, the process operations for forming the STI structure 112 and the associated liner(s) 204 (illustrated in FIGS. 11F-11I) may be omitted. Thus, a dummy liner 1102 and a dummy DTI structure 1104 may be formed in a recess 406 in the front side of the semiconductor layer 108 and then replaced with the DTI structure 114 and the high-k dielectric liner 202 from the back side of the semiconductor layer 108.

FIG. 16D illustrates an example implementation 1606 of a DTI structure 114. As shown in FIG. 16D, the example implementation 1606 of the DTI structure 114 is similar to the example implementation 708 illustrated in FIG. 7D. However, in the example implementation 1606, the DTI structure 114 extends fully between the front side surface and the back side surface of the semiconductor layer 108. Thus, a portion of the high-k dielectric liner 202 at a first end (e.g., an air gap 210) of the DTI structure 114 may be in contact with a dielectric layer 116 in the interconnect layer 104 on the front side of the device layer 102, and a second end (e.g., a plug 208) of the DTI structure 114 may be in contact with the dielectric layer 628 over the back side surface of the semiconductor layer 108.

The example implementation 1606 of the DTI structure 114 and the high-k dielectric liner 202 may be formed by similar processes illustrated and described in connection with FIGS. 11A-11L and 12A-12C. However, the process operations for forming the STI structure 112 and the associated liner(s) 204 (illustrated in FIGS. 11F-11I) may be omitted. Thus, a dummy liner 1102 and a dummy DTI structure 1104 may be formed in a recess 406 in the front side of the semiconductor layer 108 and then replaced with the DTI structure 114 and the high-k dielectric liner 202 from the back side of the semiconductor layer 108.

As indicated above, FIGS. 16A-16D are provided as examples. Other examples may differ from what is described with regard to FIGS. 16A-16D.

FIGS. 17A and 17B are diagrams of an example semiconductor device 1700 described herein. FIG. 17A illustrates a cross-section view of the semiconductor device 1700, and FIG. 17B illustrates a top view of the semiconductor device 1700 showing the location of the cross-section along the line A-A in FIG. 17A.

As shown in FIG. 17A, the semiconductor device 1700 is similar to the semiconductor device 1500 and includes a similar combination and arrangement of layers and structures as the semiconductor device 1500. However, in the semiconductor device 1700, the DTI structures 114 include one or more metals as opposed to dielectric materials or polysilicon. Examples of such metals that may be included in the DTI structures 114 include copper (Cu), aluminum (Al), aluminum copper (AlCu), and/or tungsten (W), among other examples.

Moreover, the DTI structures 114 may be electrically connected to a DTI bias pad 1702. The DTI bias pad 1702 may be electrically connected to a connection structure 128, which enables an electrical bias to be applied to the DTI structures 114 through the connection structure 128 and the DTI bias pad 1702. The electrical bias can be used to passivate damage (e.g., dangling bonds and other types of damage) to the semiconductor layer 108 around the DTI structures 114 that might have occurred from etching the semiconductor layer 108 to form the recesses (e.g., the recesses 406, the recesses 1106) for the DTI structures 114.

As shown in the top view in FIG. 17B, the DTI structures 114 may be arranged in a grid around the integrated circuit structures 110 (e.g., the photodiodes of pixel sensors in the semiconductor layer 108). The DTI bias pad 1702 may be electrically coupled and/or physically coupled to the grid, and a connection structure 128 may be included on the DTI bias pad 1702. The DTI bias pad 1702 may be spaced apart from an adjacent through-substrate interconnect structure 622 that may be connected to another connection structure 128.

As indicated above, FIGS. 17A and 17B are provided as an example. Other examples may differ from what is described with regard to FIGS. 17A and 17B.

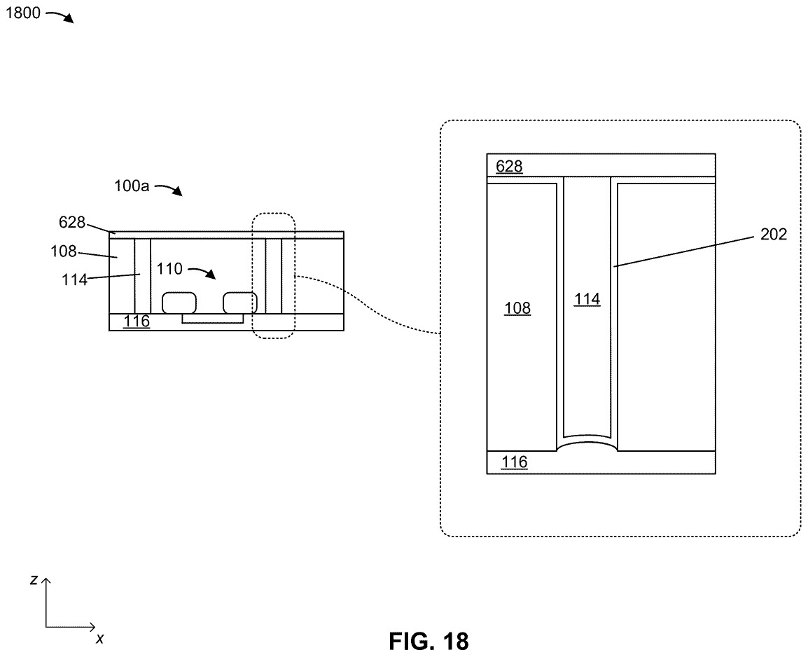

FIG. 18 is a diagram of example implementation 1800 of a DTI structure 114 described herein. The example implementation 1800 of a DTI structure 114 illustrated in FIG. 18 may be implemented in the semiconductor device 1700 and/or in another semiconductor device. As shown in FIG. 18, the example implementation 1800 of the DTI structure 114 is similar to the example implementation 1604 illustrated in FIG. 16C. However, in the example implementation 1800, the DTI structure 114 includes one or more metal materials as opposed to the material of the dielectric layer 628. The top of the DTI structure 114 may be in contact with the dielectric layer 628.

As indicated above, FIG. 18 is provided as an example. Other examples may differ from what is described with regard to FIG. 18.

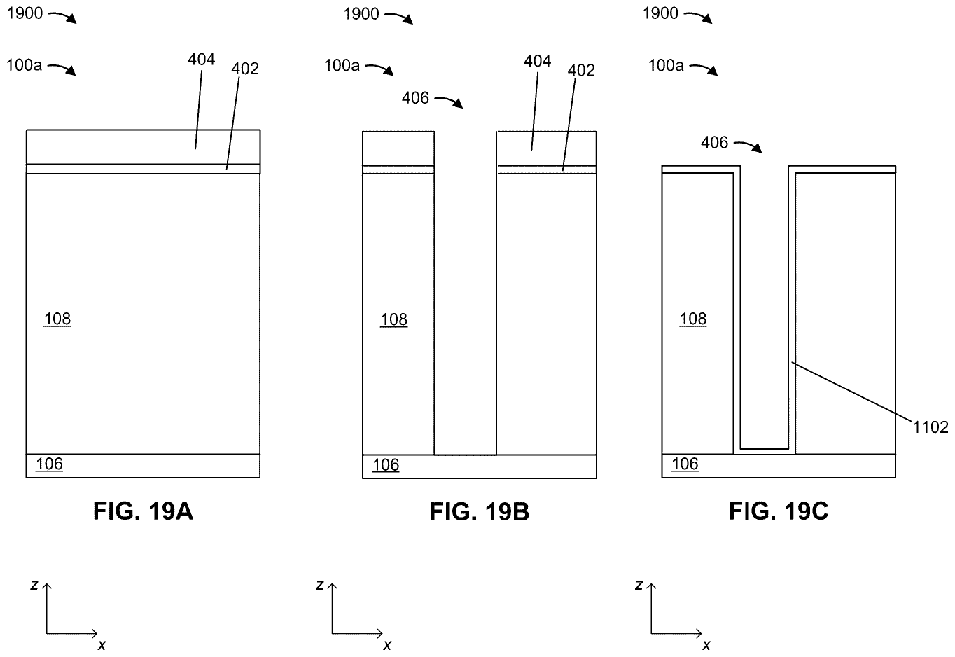

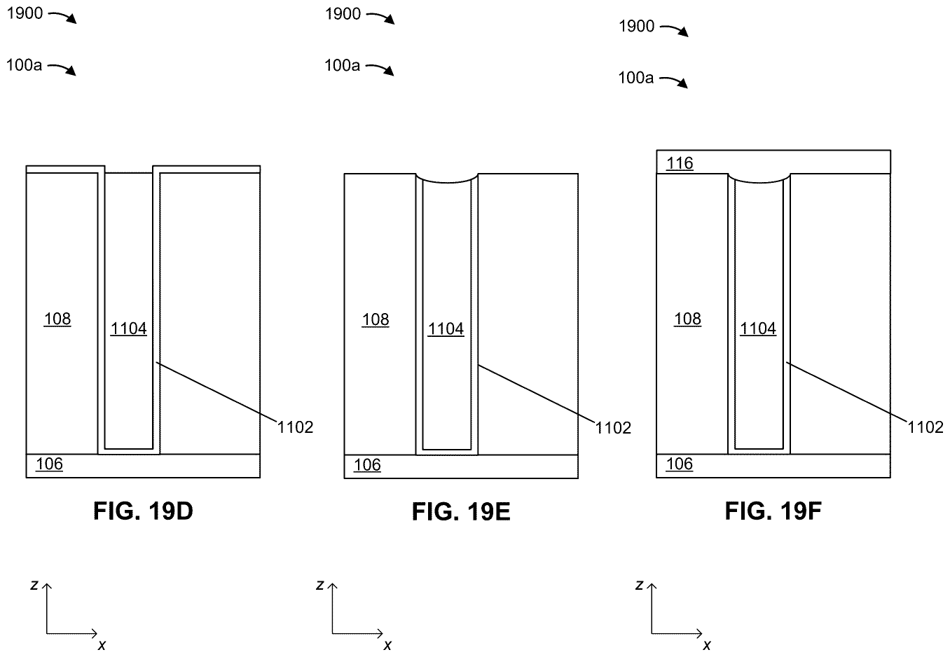

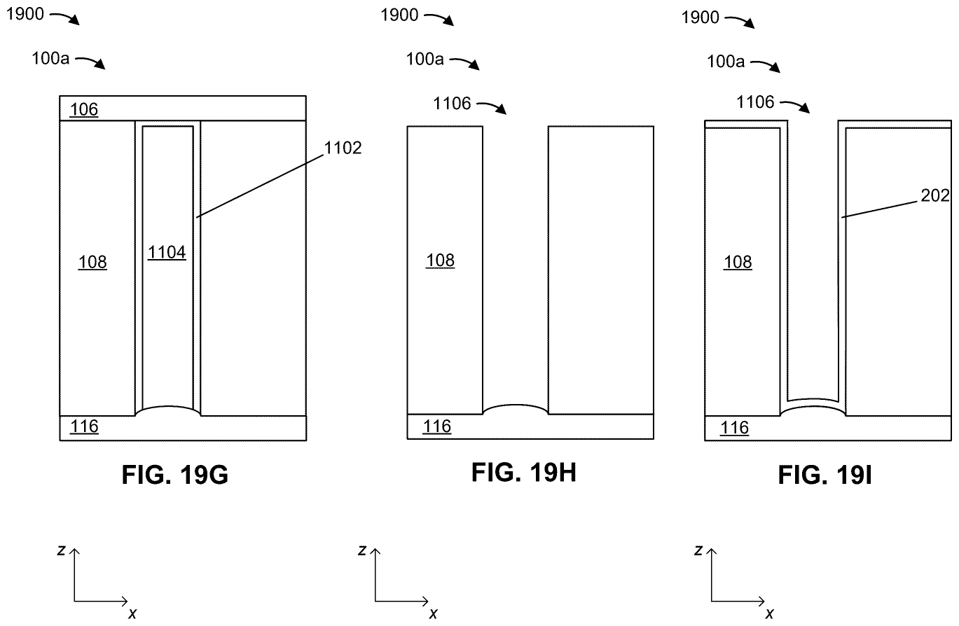

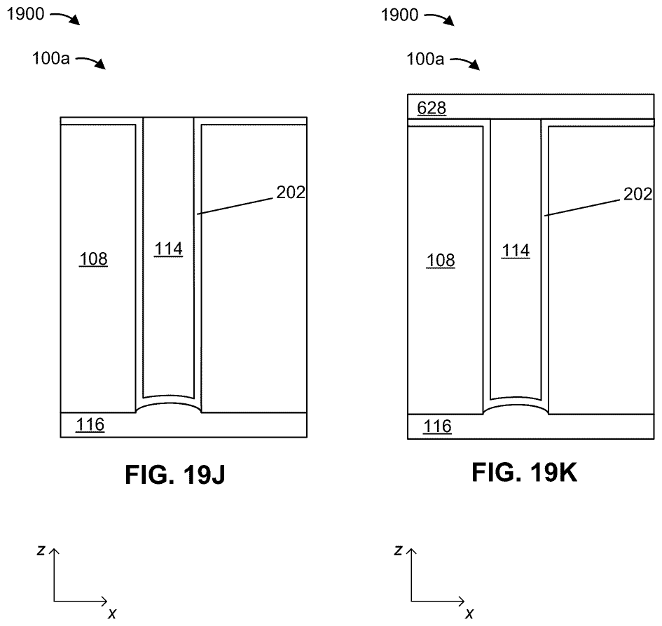

FIGS. 19A-19K are diagrams of an example implementation 1900 of forming a semiconductor device described herein. In some implementations, the example implementation 1900 includes an example process for forming the example implementation 1800 of the DTI structure 114 illustrated in FIG. 18. In some implementations, one or more of the operations described in connection with the example implementation 1900 may be performed to form a DTI structure 114 in a semiconductor device described herein, such as a semiconductor device 100, a semiconductor device 600, a semiconductor device 1300, a semiconductor device 1500, a semiconductor device 1700, a semiconductor structure 100a, a semiconductor structure 100b, and/or another semiconductor device described herein. In some implementations, one or more semiconductor processing tools may be used to perform one or more of the operations described in connection with the example implementation 1900, such as a deposition tool, an exposure tool, a developer tool, an etch tool, a planarization tool, a plating tool, an ion implantation tool, an annealing tool, a bonding tool, and/or another type of semiconductor processing tool.

As shown in FIGS. 19A-19K, the example implementation 1800 of the DTI structure 114 and the high-k dielectric liner 202 may be formed by similar processes illustrated and described in connection with FIGS. 11A-11O. However, the process operations for forming the STI structure 112 and the associated liner(s) 204 (illustrated in FIGS. 11F-11I) may be omitted, and the recess 1106 may be filled in with metal material to form the DTI structure 114, as shown in FIG. 19J. As shown in FIG. 19K, the dielectric layer 628 may be formed on the top of the DTI structure 114.

As indicated above, FIGS. 19A-19K are provided as an example. Other examples may differ from what is described with regard to FIGS. 19A-19K.

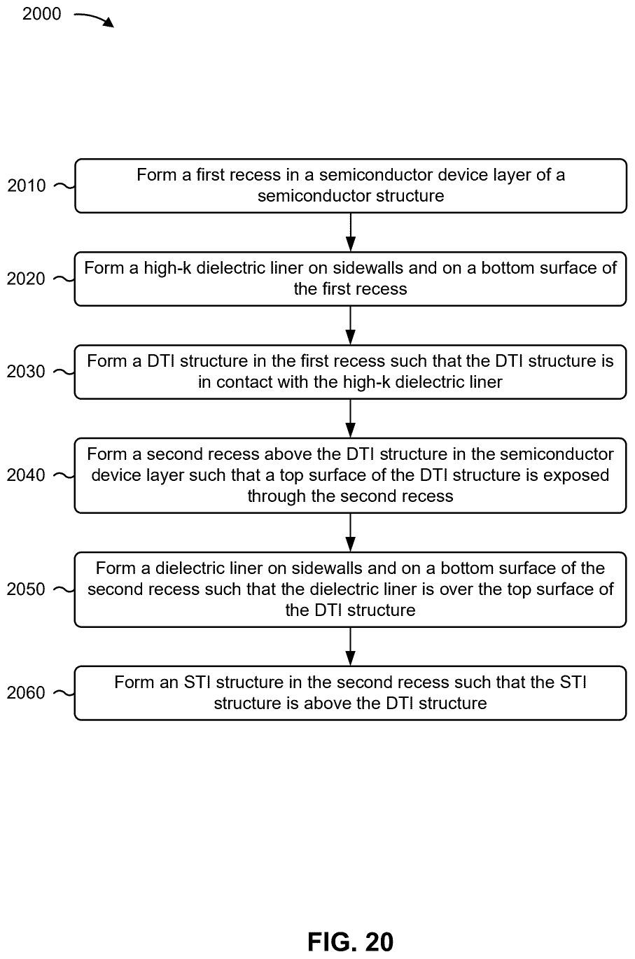

FIG. 20 is a flowchart of an example process 2000 associated with forming a semiconductor device described herein. In some implementations, one or more process blocks of FIG. 20 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 20, process 2000 may include forming a first recess in a semiconductor device layer of a semiconductor structure (block 2010). For example, one or more semiconductor processing tools may be used to form a first recess (e.g., a recess 406) in a semiconductor device layer (e.g., a device layer 102, a semiconductor layer 108) of a semiconductor structure (e.g., a semiconductor device 100, a semiconductor structure 100a), as described herein.

As further shown in FIG. 20, process 2000 may include forming a high-k dielectric liner on sidewalls and on a bottom surface of the first recess (block 2020). For example, one or more semiconductor processing tools may be used to form a high-k dielectric liner (e.g., a high-k dielectric liner 202) on sidewalls and on a bottom surface of the first recess, as described herein.

As further shown in FIG. 20, process 2000 may include forming a DTI structure in the first recess such that the DTI structure is in contact with the high-k dielectric liner (block 2030). For example, one or more semiconductor processing tools may be used to form a DTI structure (e.g., a DTI structure 114) in the first recess such that the DTI structure is in contact with the high-k dielectric liner, as described herein.

As further shown in FIG. 20, process 2000 may include forming a second recess above the DTI structure in the semiconductor device layer such that a top surface of the DTI structure is exposed through the second recess (block 2040). For example, one or more semiconductor processing tools may be used to form a second recess (e.g., a recess 414) above the DTI structure in the semiconductor device layer such that a top surface of the DTI structure is exposed through the second recess, as described herein.

As further shown in FIG. 20, process 2000 may include forming a dielectric liner on sidewalls and on a bottom surface of the second recess such that the dielectric liner is over the top surface of the DTI structure (block 2050). For example, one or more semiconductor processing tools may be used to form a dielectric liner (e.g., a liner 204) on sidewalls and on a bottom surface of the second recess such that the dielectric liner is over the top surface of the DTI structure, as described herein. In some implementations, a dielectric constant of the high-k dielectric liner is greater than a dielectric constant of the dielectric liner.

As further shown in FIG. 20, process 2000 may include forming an STI structure in the second recess such that the STI structure is above the DTI structure (block 2060). For example, one or more semiconductor processing tools may be used to form an STI structure (e.g., an STI structure 112) in the second recess such that the STI structure is above the DTI structure, as described herein.

Process 2000 may include additional implementations, such as any single implementation or any combination of implementations described below and/or in connection with one or more other processes described elsewhere herein.

In a first implementation, forming the recess includes forming the recess such that a bottom surface of the recess extends into an STI structure in the semiconductor device layer, and wherein forming the high-k dielectric liner comprises forming the high-k dielectric liner on a portion of the sidewalls of the recess in the STI structure.

In a second implementation, alone or in combination with the first implementation, the high-k dielectric liner includes a high-k dielectric material having a dielectric constant that is greater than a dielectric constant of silicon nitride (SiₓN_{y}).

In a third implementation, alone or in combination with one or more of the first and second implementations, the high-k dielectric liner includes at least one of an aluminum oxide (AlₓO_{y}), a tantalum oxide (TaₓO_{y}), a titanium oxide (TiOₓ), a zirconium oxide (ZrOₓ), strontium titanium oxide (SrTiOₓ), hafnium silicon oxide (HfSiOₓ), lanthanum oxide (LaₓO_{y}), yttrium oxide (YₓO_{y}), and/or amorphous lanthanum aluminum oxide (a-LaAlOₓ), and/or a hafnium oxide (HfOₓ), among other examples.

In a fourth implementation, alone or in combination with one or more of the first through third implementations, process 2000 includes performing a planarization operation to planarize a back side of the semiconductor device layer, where a portion of the high-k dielectric liner at a bottom of the DTI structure is removed during the planarization operation, and forming another high-k dielectric liner (e.g., a high-k dielectric liner 702) over the back side of the semiconductor device layer such that the other high-k dielectric liner is over the bottom of the DTI structure.

In a fifth implementation, alone or in combination with one or more of the first through fourth implementations, forming the DTI structure in the first recess includes filling the first recess with dielectric material to form the DTI structure.

In a sixth implementation, alone or in combination with one or more of the first through fifth implementations, forming the DTI structure in the first recess includes depositing dielectric material into the first recess such that a dielectric plug (e.g., a plug 208) of the DTI structure seals the first recess before the first recess is fully filled in with the dielectric material, resulting in the DTI structure comprising an air gap (e.g., an air gap 210) in the first recess.

In a seventh implementation, alone or in combination with one or more of the first through sixth implementations, process 2000 includes performing a planarization operation to planarize a back side of the semiconductor device layer, where a portion of the high-k dielectric liner at a bottom of the DTI structure is removed during the planarization operation, and where the planarization operation results in the air gap being opened to the back side of the semiconductor device layer, forming another high-k dielectric liner (e.g., a high-k dielectric liner 702) over the back side of the semiconductor device layer, where the air gap being opened to the back side of the semiconductor device layer results in the other high-k dielectric liner being formed on the dielectric plug and on sidewalls of the air gap, and depositing a dielectric layer (e.g., a dielectric layer 628) over the back side of the semiconductor device layer such that the dielectric layer seals the air gap before the air gap is fully filled in with material of the dielectric layer.

In an eighth implementation, alone or in combination with one or more of the first through seventh implementations, the sidewalls of the air gap correspond to the high-k dielectric liner.

Although FIG. 20 shows example blocks of process 2000, in some implementations, process 2000 includes additional blocks, fewer blocks, different blocks, or differently arranged blocks than those depicted in FIG. 20. Additionally, or alternatively, two or more of the blocks of process 2000 may be performed in parallel.

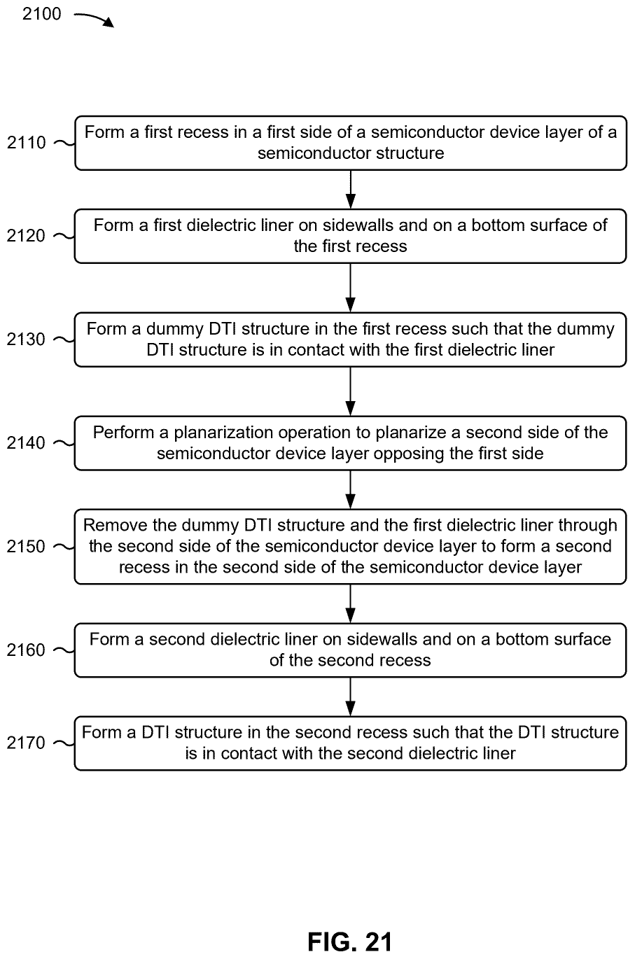

FIG. 21 is a flowchart of an example process 2100 associated with forming a semiconductor device described herein. In some implementations, one or more process blocks of FIG. 21 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 21, process 2100 may include forming a first recess in a first side of a semiconductor device layer of a semiconductor structure (block 2110). For example, one or more semiconductor processing tools may be used to form a first recess (e.g., a recess 406) in a first side of a semiconductor device layer (e.g., a device layer 102, a semiconductor layer 108) of a semiconductor structure (e.g., a semiconductor device 100, a semiconductor structure 100a), as described herein.

As further shown in FIG. 21, process 2100 may include forming a first dielectric liner on sidewalls and on a bottom surface of the first recess (block 2120). For example, one or more semiconductor processing tools may be used to form a first dielectric liner (e.g., a dummy liner 1102) on sidewalls and on a bottom surface of the first recess, as described herein.

As further shown in FIG. 21, process 2100 may include forming a dummy DTI structure in the first recess such that the dummy DTI structure is in contact with the first dielectric liner (block 2130). For example, one or more semiconductor processing tools may be used to form a dummy DTI structure (e.g., a dummy DTI structure 1104) in the first recess such that the dummy DTI structure is in contact with the first dielectric liner, as described herein.

As further shown in FIG. 21, process 2100 may include performing a planarization operation to planarize a second side of the semiconductor device layer opposing the first side (block 2140). For example, one or more semiconductor processing tools may be used to perform a planarization operation to planarize a second side of the semiconductor device layer opposing the first side, as described herein. In some implementations, a portion of the first dielectric liner at a bottom of the dummy DTI structure is removed during the planarization operation such that the bottom of the dummy DTI structure is exposed through the second side of the semiconductor device layer.

As further shown in FIG. 21, process 2100 may include removing the dummy DTI structure and the first dielectric liner through the second side of the semiconductor device layer to form a second recess in the second side of the semiconductor device layer (block 2150). For example, one or more semiconductor processing tools may be used to remove the dummy DTI structure and the first dielectric liner through the second side of the semiconductor device layer to form a second recess (e.g., a recess 1106) in the second side of the semiconductor device layer, as described herein.

As further shown in FIG. 21, process 2100 may include forming a second dielectric liner on sidewalls and on a bottom surface of the second recess (block 2160). For example, one or more semiconductor processing tools may be used to form a second dielectric liner (e.g., a high-k dielectric liner 202) on sidewalls and on a bottom surface of the second recess, as described herein. In some implementations, a dielectric constant of the second dielectric liner is greater than a dielectric constant of the first dielectric liner.

As further shown in FIG. 21, process 2100 may include forming a DTI structure in the second recess such that the DTI structure is in contact with the second dielectric liner (block 2170). For example, one or more semiconductor processing tools may be used to form a DTI structure (e.g., a DTI structure 114) in the second recess such that the DTI structure is in contact with the second dielectric liner, as described herein.

Process 2100 may include additional implementations, such as any single implementation or any combination of implementations described below and/or in connection with one or more other processes described elsewhere herein.

In a first implementation, the first dielectric liner includes at least one of a silicon oxide (SiOₓ), or a silicon nitride (SiₓN_{y}), and wherein the second dielectric liner comprises a high-k dielectric material having a dielectric constant that is greater than a dielectric constant of silicon nitride (SiₓN_{y}).

In a second implementation, alone or in combination with the first implementation, the second dielectric liner comprises at least one of a strontium titanium oxide (SrTiOₓ), a hafnium silicon oxide (HfSiOₓ), a lanthanum oxide (LaₓO_{y}), an yttrium oxide (YₓO_{y}), an aluminum oxide (AlₓO_{y}), a tantalum oxide (TaₓO_{y}), a titanium oxide (TiOₓ), a zirconium oxide (ZrOₓ), or a hafnium oxide (HfOₓ), and/or an amorphous lanthanum aluminum oxide (a-LaAlOₓ), among other examples.

In a third implementation, alone or in combination with one or more of the first and second implementations, forming the DTI structure in the second recess includes filling the second recess with metal material to form the DTI structure.

In a fourth implementation, alone or in combination with one or more of the first through third implementations, forming the DTI structure in the second recess includes filling the second recess with at least one of a dielectric material or a polysilicon material to form the DTI structure.

In a fifth implementation, alone or in combination with one or more of the first through fourth implementations, forming the DTI structure in the second recess includes depositing a dielectric layer (e.g., a dielectric layer 628) over the second side of the semiconductor device layer such that the dielectric layer seals the second recess before the second recess is fully filled in with material of the dielectric layer, resulting in the DTI structure comprising an air gap.

In a sixth implementation, alone or in combination with one or more of the first through fifth implementations, forming the DTI structure in the second recess includes forming the DTI structure in the second recess such that the DTI structure extends from the second side of the semiconductor device layer to the first side of the semiconductor device layer.

Although FIG. 21 shows example blocks of process 2100, in some implementations, process 2100 includes additional blocks, fewer blocks, different blocks, or differently arranged blocks than those depicted in FIG. 21. Additionally, or alternatively, two or more of the blocks of process 2100 may be performed in parallel.

In this way, a liner for an isolation structure is formed in a device layer of a semiconductor device using one or more high-k dielectric materials. The high-k dielectric material(s) of the liner have a dielectric constant that is greater than the dielectric constant of silicon nitride (SiₓN_{y}), which enables increased passivation to be achieved for the isolation, and enables reduced current leakage to be achieved for integrated circuit structures in the device layer. The isolation structure and/or the liner may be formed by processes that are compatible with subsequent layers and/or structures that are to be formed in the semiconductor device. For example, the isolation structure may be a DTI structure, and an STI structure may be formed on the DTI structure such that the STI structure is located between the liner and the front side surface of the device layer. In this way, the STI structure acts as a buffer and protects subsequent layers and/or structures formed above the front side surface of the device layer from being contaminated by the high-k dielectric material(s) of the liner. Additionally and/or alternatively, the DTI structure and the associated liner may be formed on the back side of the device layer. A dummy DTI structure and a dummy liner may be formed in the front side of the device layer and subsequently replaced from the back side of the device layer with the DTI structure and the associated liner. This enables the recess for the DTI structure to be formed using plasma-based processes prior to formation of layers and/or structures being formed above the front side of the device layer, while the back side processing protects subsequent layers and/or structures formed above the front side surface of the device layer from being contaminated by the high-k dielectric material(s) of the liner.

As described in greater detail above, some implementations described herein provide a method. The method includes forming a first recess in a semiconductor device layer of a semiconductor structure. The method includes forming a high-k dielectric liner on sidewalls and on a bottom surface of the first recess. The method includes forming a DTI structure in the first recess such that the DTI structure is in contact with the high-k dielectric liner. The method includes forming a second recess above the DTI structure in the semiconductor device layer such that a top surface of the DTI structure is exposed through the second recess. The method includes forming a dielectric liner on sidewalls and on a bottom surface of the second recess such that the dielectric liner is over the top surface of the DTI structure, where a dielectric constant of the high-k dielectric liner is greater than a dielectric constant of the dielectric liner. The method includes forming a STI structure in the second recess such that the STI structure is above the DTI structure.

As described in greater detail above, some implementations described herein provide a method. The method includes forming a first recess in a first side of a semiconductor device layer of a semiconductor structure. The method includes forming a first dielectric liner on sidewalls and on a bottom surface of the first recess. The method includes forming a dummy DTI structure in the first recess such that the dummy DTI structure is in contact with the first dielectric liner. The method includes performing a planarization operation to planarize a second side of the semiconductor device layer opposing the first side, where a portion of the first dielectric liner at a bottom of the dummy DTI structure is removed during the planarization operation such that the bottom of the dummy DTI structure is exposed through the second side of the semiconductor device layer. The method includes removing the dummy DTI structure and the first dielectric liner through the second side of the semiconductor device layer to form a second recess in the second side of the semiconductor device layer. The method includes forming a second dielectric liner on sidewalls and on a bottom surface of the second recess, where a dielectric constant of the second dielectric liner is greater than a dielectric constant of the first dielectric liner. The method includes forming a DTI structure in the second recess such that the DTI structure is in contact with the second dielectric liner.

As described in greater detail above, some implementations described herein provide a semiconductor device. The semiconductor device includes a semiconductor device layer. The semiconductor device includes one or more integrated circuit structures in the semiconductor device layer. The semiconductor device includes a DTI structure adjacent to an integrated circuit structure of the one or more integrated circuit structures, where the DTI structure is located in the semiconductor device layer between a first side of the semiconductor device layer and a second side of the semiconductor device layer vertically opposing the first side. The semiconductor device includes a first high-k dielectric liner between sidewalls of the DTI structure and the semiconductor device layer. The semiconductor device includes a second high-k dielectric liner on the second side of the semiconductor layer, where at least one of the first high-k dielectric liner or the second high-k dielectric liner is in contact with at least one of a top of the DTI structure or a bottom of the DTI structure. The semiconductor device includes an interconnect structure vertically adjacent to the first side of the semiconductor device layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first recess in a semiconductor device layer of a semiconductor structure;
forming a high dielectric constant (high-k) dielectric liner on sidewalls and on a bottom surface of the first recess;
forming a deep trench isolation (DTI) structure in the first recess such that the DTI structure is in contact with the high-k dielectric liner;
forming a second recess above the DTI structure in the semiconductor device layer such that a top surface of the DTI structure is exposed through the second recess;
forming a dielectric liner on sidewalls and on a bottom surface of the second recess such that the dielectric liner is over the top surface of the DTI structure,
wherein a dielectric constant of the high-k dielectric liner is greater than a dielectric constant of the dielectric liner; and
forming a shallow trench isolation (STI) structure in the second recess such that the STI structure is above the DTI structure.

2. The method of claim 1, wherein forming the second recess comprises:
forming the second recess such that a bottom surface of the second recess extends into the STI DTI structure; and
wherein forming the dielectric liner comprises:
forming the dielectric liner on a top of the DTI structure.

3. The method of claim 1, wherein the high-k dielectric liner comprises a high-k dielectric material having a dielectric constant that is greater than a dielectric constant of silicon nitride (SiₓN_{y}).

4. The method of claim 1, wherein the high-k dielectric liner comprises at least one of:
an aluminum oxide (AlₓO_{y}),
a tantalum oxide (TaₓO_{y}),
a titanium oxide (TiOₓ),
a zirconium oxide (ZrOₓ),
a strontium titanium oxide (SrTiOₓ),
a hafnium silicon oxide (HfSiOₓ),
a lanthanum oxide (LaₓO_{y}),
a yttrium oxide (YₓO_{y}),
an amorphous lanthanum aluminum oxide (a-LaAlOₓ), or
a hafnium oxide (HfOₓ).

5. The method of claim 1, further comprising:
performing a planarization operation to planarize a back side of the semiconductor device layer,
wherein a portion of the high-k dielectric liner at a bottom of the DTI structure is removed during the planarization operation; and
forming another high-k dielectric liner over the back side of the semiconductor device layer such that the other high-k dielectric liner is over the bottom of the DTI structure.

6. The method of claim 1, wherein forming the DTI structure in the first recess comprises:
filling the first recess with dielectric material to form the DTI structure.

7. The method of claim 1, wherein forming the DTI structure in the first recess comprises:
depositing dielectric material into the first recess such that a dielectric plug of the DTI structure seals the first recess before the first recess is fully filled in with the dielectric material, resulting in the DTI structure comprising an air gap in the first recess.

8. The method of claim 7, further comprising:
performing a planarization operation to planarize a back side of the semiconductor device layer,
wherein a portion of the high-k dielectric liner at a bottom of the DTI structure is removed during the planarization operation, and
wherein the planarization operation results in the air gap being opened to the back side of the semiconductor device layer;
forming another high-k dielectric liner over the back side of the semiconductor device layer,
wherein the air gap being opened to the back side of the semiconductor device layer results in the other high-k dielectric liner being formed on the dielectric plug and on sidewalls of the air gap; and
depositing a dielectric layer over the back side of the semiconductor device layer such that the dielectric layer seals the air gap before the air gap is fully filled in with material of the dielectric layer.

9. The method of claim 8, wherein the sidewalls of the air gap correspond to the high-k dielectric liner.

10. A method, comprising:
forming a first recess in a first side of a semiconductor device layer of a semiconductor structure;
forming a first dielectric liner on sidewalls and on a bottom surface of the first recess;
forming a dummy deep trench isolation (DTI) structure in the first recess such that the dummy DTI structure is in contact with the first dielectric liner;
performing a planarization operation to planarize a second side of the semiconductor device layer opposing the first side,
wherein a portion of the first dielectric liner at a bottom of the dummy DTI structure is removed during the planarization operation such that the bottom of the dummy DTI structure is exposed through the second side of the semiconductor device layer;
removing the dummy DTI structure and the first dielectric liner through the second side of the semiconductor device layer to form a second recess in the second side of the semiconductor device layer;
forming a second dielectric liner on sidewalls and on a bottom surface of the second recess,
wherein a dielectric constant of the second dielectric liner is greater than a dielectric constant of the first dielectric liner; and
forming a DTI structure in the second recess such that the DTI structure is in contact with the second dielectric liner.

11. The method of claim 10, wherein the first dielectric liner comprises at least one of:
a silicon oxide (SiOₓ), or
a silicon nitride (SiₓN_{y}); and
wherein the second dielectric liner comprises a high-k dielectric material having a dielectric constant that is greater than a dielectric constant of silicon nitride (SiₓN_{y}).

12. The method of claim 10, wherein the second dielectric liner comprises at least one of:
a strontium titanium oxide (SrTiOₓ),
a hafnium silicon oxide (HfSiOₓ),
a lanthanum oxide (LaₓO_{y}),
an yttrium oxide (YₓO_{y}),
an aluminum oxide (AlₓO_{y}),
a tantalum oxide (TaₓO_{y}),
a titanium oxide (TiOₓ),
a zirconium oxide (ZrOₓ),
a hafnium oxide (HfOₓ), or
an amorphous lanthanum aluminum oxide (a-LaAlOₓ).

13. The method of claim 10, wherein forming the DTI structure in the second recess comprises:
filling the second recess with metal material to form the DTI structure.

14. The method of claim 10, wherein forming the DTI structure in the second recess comprises:
filling the second recess with at least one of a dielectric material or a polysilicon material to form the DTI structure.

15. The method of claim 10, wherein forming the DTI structure in the second recess comprises:
depositing a dielectric layer over the second side of the semiconductor device layer such that the dielectric layer seals the second recess before the second recess is fully filled in with material of the dielectric layer, resulting in the DTI structure comprising an air gap.

16. The method of claim 10, wherein forming the DTI structure in the second recess comprises:
forming the DTI structure in the second recess such that the DTI structure extends from the second side of the semiconductor device layer to the first side of the semiconductor device layer.

17. A semiconductor device, comprising:
a semiconductor device layer;
one or more integrated circuit structures in the semiconductor device layer;
a deep trench isolation (DTI) structure adjacent to an integrated circuit structure of the one or more integrated circuit structures,
wherein the DTI structure is located in the semiconductor device layer between a first side of the semiconductor device layer and a second side of the semiconductor device layer vertically opposing the first side;
a first high dielectric constant (high-k) dielectric liner between sidewalls of the DTI structure and the semiconductor device layer;
a second high-k dielectric liner on the second side of the semiconductor layer,
wherein at least one of the first high-k dielectric liner or the second high-k dielectric liner is in contact with at least one of a top of the DTI structure or a bottom of the DTI structure; and
an interconnect structure vertically adjacent to the first side of the semiconductor device layer.

18. The semiconductor device of claim 17, wherein a portion of the semiconductor device layer is located between the first high-k dielectric liner and the second high-k dielectric liner.

19. The semiconductor device of claim 17, wherein a portion of the first high-k dielectric liner is in contact with the second high-k dielectric liner.

20. The semiconductor device of claim 17, wherein the DTI structure comprises;
an air gap; and
a dielectric plug,
wherein the second high-k dielectric liner is located between the air gap and the dielectric plug.
